(19) United States
(12) Patent Application Publication
(10) Pub. No.: US 2006/0103412 A1
(43) Pub. Date: May 18, 2006

(54) Display device

(76) Inventors: Yohei Kimura, Ishikawa-gun (JP); Koji Nakayama, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/259,178

(22) Filed: Oct. 27, 2005

(30) Foreign Application Priority Data
Oct. 29, 2004 (JP) 2004-316561
Oct. 29, 2004 (JP) 2004-316562
Oct. 29, 2004 (JP) 2004-316563
Oct. 29, 2004 (JP) 2004-316564
Oct. 29, 2004 (JP) 2004-316565
Oct. 29, 2004 (JP) 2004-316566
Feb. 1, 2005 (JP) 2005-025500
Feb. 1, 2005 (JP) 2005-025501
Feb. 17, 2005 (JP) 2005-040790
Feb. 17, 2005 (JP) 2005-040791

(51) Int. Cl. G01R 31/00

(52) U.S. Cl. 324/770

(57) ABSTRACT

There is disclosed a display device comprising an effective display section constituted of a plurality of system pixels, an inspection wiring line to which a signal for inspection is supplied in inspecting the effective display section, and a conductive layer having a discharge inducing section which is disposed in such a manner as to face the inspection wiring line at a predetermined interval and which induces discharge of electric charges accumulated in the inspection wiring line.

### CROSS-REFERENCE TO RELATED APPLICATIONS

This application is based upon and claims the benefit of priority from prior Japanese Patent Applications No. 2004-316561, filed Oct. 29, 2004; No. 2004-316562, filed Oct. 29, 2004; No. 2004-316563, filed Oct. 29, 2004; No. 2004-316564, filed Oct. 29, 2004; No. 2004-316565, filed Oct. 29, 2004; No. 2004-316566, filed Oct. 29, 2004; No. 2005-025500, filed Feb. 1, 2005; No. 2005-025501, filed Feb. 1, 2005; No. 2005-040790, filed Feb. 17, 2005; and No. 2005-040791, filed Feb. 17, 2005, the entire contents of all of which are incorporated herein by reference.

### BACKGROUND OF THE INVENTION

1. Field of the Invention

The present invention relates to a display device, more particularly to a display device including an inspection section for performing inspection of a quality.

2. Description of the Related Art

A display device such as a liquid crystal display includes an effective display section constituted of display pixels in a matrix. This effective display section comprises a plurality of scan lines extending along a row direction of the display pixels; a plurality of signal lines extending along a column direction of the display pixels; switch elements disposed in the vicinity of intersections of the scan lines and the signal lines; pixel electrodes connected to the switch elements and the like. These scan lines and signal lines are drawn out to an outer peripheral portion of the effective display section.

In recent years, with an increase of the display pixels, various wiring lines such as the scan lines or the signal lines are disposed adjacent to one another with fine line widths and at small intervals in the effective display section and the outer peripheral portion of the section. Therefore, wiring defects such as short-circuit between the wiring lines and line breakage of each wiring line need to be strictly inspected. For example, there is proposed a method of connecting an inspection control circuit to the liquid crystal display and supplying signals having different phases to the adjacent scan lines to thereby inspect the wiring defects (see, e.g., Jpn. Pat. Appln. KOKAI Publication No. 06-160898. There is also proposed a liquid crystal display having an inspection wiring line in the outer peripheral portion of the effective display section (see, e.g., Jpn. Pat. Appln. KOKAI Publication No. 2003-157053).

Moreover, in order to cope with an adverse influence of charging on a manufacturing process, there are disclosed: a method (see, e.g., Jpn. Pat. Appln. KOKAI Publication No. 02-7019) of manufacturing a liquid crystal display in which an auxiliary pattern for discharging is disposed at a predetermined interval in the same layer as that of a transparent electrode for displaying; an electrode wiring line substrate (see, e.g., Jpn. Pat. Appln. KOKAI Publication No. 11-282016) in which a first electrode wiring line and a second electrode wiring line disposed via an insulating layer have a discharging portion in a position facing the wiring lines and the like.

### BRIEF SUMMARY OF THE INVENTION

The present invention has been developed in view of the above-described problem, and an object thereof is to provide a display device in which an inspection of a quality can be stably conducted, and a drop of a manufacturing yield can be suppressed.

According to the present invention, there is provided a display device comprising:

an effective display section constituted of a plurality of display pixels;

a wiring line for inspection to which a signal for inspection is supplied in inspecting the effective display section; and

a conductive layer having a discharge inducing section which is disposed in such a manner as to face the wiring line for inspection at a predetermined interval and which induces discharge of electric charges accumulated in the wiring line for inspection.

According to the present invention, there can be provided the display device in which it is possible to conduct the inspection of the quality stably and suppress the drop of the manufacturing yield.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram schematically showing a constitution of a liquid crystal display panel of a liquid crystal display according to one embodiment of the present invention;

FIG. 2 is a diagram schematically showing a constitution of an inspection section of the liquid crystal display panel shown in FIG. 1;

FIG. 3 is a diagram showing occurrence of a short-circuit attributable to discharge in a switch element positioned in the vicinity of an end portion of a control wiring line for inspection;

FIG. 4 is an explanatory view of occurrence of line breakage attributable to the discharge in the vicinity of a bent portion of a common wiring line;

FIG. 5 is a diagram schematically showing a constitution of a mother substrate for the display device before a single liquid crystal display panel is cut out as shown in FIG. 1;

FIG. 6A is a plan view schematically showing a wiring example of a wiring line for inspection and a conductive layer facing the wiring line;

FIG. 6B is a sectional view schematically showing a sectional structure at a time when the wiring line for inspection and the conductive layer shown in FIG. 6A are cut along a line A-A′;

FIG. 7A is a plan view schematically showing an arrangement example of the wiring line for inspection and the conductive layer facing this wiring line;

FIG. 7B is a sectional view schematically showing a sectional structure at a time when the wiring line for inspection and the conductive layer shown in FIG. 7A are cut along the line A-A′;

FIG. 8A is a plan view schematically showing an arrangement example of the wiring line for inspection and the conductive layer superimposed on this wiring line;

FIG. 8B is a sectional view schematically showing a sectional structure at a time when the wiring line for inspection and the conductive layer shown in FIG. 8A are cut along the line A-A′;

FIG. 9A is a plan view schematically showing shape examples of a discharge inducing section of the wiring line for inspection and a facing portion of the conductive layer;

FIG. 9B is a plan view schematically showing shape examples of the discharge inducing section of the wiring line for inspection and the facing portion of the conductive layer;

FIG. 9C is a plan view schematically showing shape examples of the discharge inducing section of the wiring line for inspection and the facing portion of the conductive layer;

FIG. 9D is a plan view schematically showing shape examples of the discharge inducing section of the wiring line for inspection and the facing portion of the conductive layer;

FIG. 10A is a plan view showing a pattern combination example at a time when the wiring line for inspection is disposed in such a manner as to face the conductive layer;

FIG. 10B is a plan view showing a pattern combination example at a time when the wiring line for inspection is disposed in such a manner as to face the conductive layer;

FIG. 10C is a plan view showing a pattern combination example at a time when the wiring line for inspection is disposed in such a manner as to face the conductive layer;

FIG. 10D is a plan view showing a pattern combination example at a time when the wiring line for inspection is disposed in such a manner as to face the conductive layer;

FIG. 11A is a plan view showing a pattern combination example at a time when the wiring line for inspection is superimposed on the conductive layer;

FIG. 11B is a plan view showing a pattern combination example at a time when the wiring line for inspection is superimposed on the conductive layer;

FIG. 11C is a plan view showing a pattern combination example at a time when the wiring line for inspection is superimposed on the conductive layer;

FIG. 11D is a plan view showing a pattern combination example at a time when the wiring line for inspection is superimposed on the conductive layer;

FIG. 11E is a plan view showing a pattern combination example at a time when the wiring line for inspection is superimposed on the conductive layer;

FIG. 12A is a plan view schematically showing an arrangement of the control wiring line for inspection and the conductive layer facing the wiring line according to Example 1;

FIG. 12B is a sectional view schematically showing a sectional structure at a time when the control wiring line for inspection and the conductive layer shown in FIG. 12A are cut along a line B-B′;

FIG. 13A is a plan view schematically showing an arrangement of the control wiring line for inspection and the conductive layer facing the wiring line according to Example 2;

FIG. 13B is a sectional view schematically showing a sectional structure at a time when the control wiring line for inspection and the conductive layer shown in FIG. 13A are cut along the line B-B′;

FIG. 14A is a plan view schematically showing an arrangement of the control wiring line for inspection and the conductive layer facing the wiring line according to Example 3;

FIG. 14B is a sectional view schematically showing a sectional structure at the time when the control wiring line for inspection and the conductive layer shown in FIG. 14A are cut along the line B-B′;

FIG. 15 is a plan view schematically showing an arrangement Example in which the wiring line for inspection face a connection pad in Embodiment 1;

FIG. 16 is a plan view schematically showing an arrangement example in which the wiring line for inspection faces a connection wiring line connected to the connection pad in Embodiment 1;

FIG. 17A is a plan view schematically showing an arrangement of the control wiring line for inspection and the connection pad according to Example 4;

FIG. 17B is an enlarged plan view of a facing portion (region B shown by a broken line in the figure) between the control wiring line for inspection and the connection pad shown in FIG. 17A;

FIG. 17C is a sectional view schematically showing a sectional structure at a time when the control wiring line for inspection and the connection pad shown in FIG. 17B are cut along a line B-B′;

FIG. 18 is a plan view schematically showing an arrangement example in which the wiring line for inspection faces a dummy pattern in Embodiment 2;

FIG. 19 is a plan view schematically showing an arrangement example in which the wiring line for inspection faces a dummy group in Embodiment 2;

FIG. 20 is a plan view schematically showing an arrangement example of the wiring line for inspection, the dummy pattern, and a wiring line capable of supplying a signal in Embodiment 2;

FIG. 21 is a plan view schematically showing an arrangement example of the wiring line for inspection, the dummy pattern, and the wiring line capable of supplying the signal in Embodiment 2;

FIG. 22A is a plan view schematically showing an arrangement of the control wiring line for inspection, the dummy group, and the connection pad according to Example 5;

FIG. 22B is an enlarged plan view of the facing portion (region B shown by a broken line in the figure) of the control wiring line for inspection, the dummy group, and the connection pad shown in FIG. 22A;

FIG. 22C is a sectional view schematically showing a sectional structure at a time when the control wiring line for inspection, the dummy group, and the connection pad shown in FIG. 22B are cut along a line B-B′;

FIG. 23 is a plan view schematically showing an arrangement Example in which the wiring line for inspection faces a branched portion of a common wiring line in Embodiment 3;

FIG. 24 is a plan view schematically showing an arrangement example in which the wiring line for inspection faces a terminal end portion of the common wiring line in Embodiment 3;

FIG. 25A is a plan view schematically showing an arrangement of the control wiring line for inspection and the common wiring line in Example 6;

FIG. 25B is an enlarged plan view of the facing portion (region B shown by a broken line in the figure) of the control wiring line for inspection and the common wiring line shown in FIG. 25A;

FIG. 25C is a sectional view schematically showing a sectional structure at a time when the control wiring line for inspection and the common wiring line shown in FIG. 25B are cut along a line B-B′;

FIG. 26 is a plan view schematically showing an arrangement example in which the wiring line for inspection faces the branched portion of a common signal line in Embodiment 4;

FIG. 27 is a plan view schematically showing an arrangement example in which the wiring line for inspection faces an end portion of the common signal line in Embodiment 4;

FIG. 28A is a plan view schematically showing an arrangement of the control wiring line for inspection and the common signal line according to Example 7;

FIG. 28B is an enlarged plan view of a facing portion (region B shown by a broken line in the figure) of the control wiring line for inspection and the common signal line shown in FIG. 28A;

FIG. 28C is a sectional view schematically showing a sectional structure at a time when the control wiring line for inspection and the common signal line shown in FIG. 28B are cut along a line B-B′;

FIG. 29A is a sectional view schematically showing a structure in the vicinity of a connecting portion of a liquid crystal display panel in Embodiment 5;

FIG. 29B is a plan view schematically showing a structure in the vicinity of the connecting portion of the liquid crystal display panel in Embodiment 5;

FIG. 30 is a plan view schematically showing an arrangement example in which the wiring line for inspection faces a power supply pad of the connecting portion in Embodiment 5;

FIG. 31 is a plan view schematically showing an arrangement example in which the wiring line for inspection faces an electrode portion of the connecting portion in Embodiment 5;

FIG. 32A is a plan view schematically showing an arrangement of the control wiring line for inspection and the connecting portion according to Example 8;

FIG. 32B is an enlarged plan view of the facing portion (region B shown by a broken line in the figure) of the control wiring line for inspection and the connecting portion shown in FIG. 32A;

FIG. 32C is a sectional view schematically showing a sectional structure at a time when the control wiring line for inspection and the connecting portion shown in FIG. 32B are cut along a line B-B′;

FIG. 33 is a plan view schematically showing an arrangement example in which the wiring line for inspection faces an alignment mark in the liquid crystal display panel in Embodiment 6;

FIG. 34 is a plan view schematically showing an arrangement example in which the wiring line for inspection faces the alignment mark in the mother substrate for the display device in Embodiment 6;

FIG. 35A is a plan view schematically showing an arrangement of the control wiring line for inspection and the alignment mark according to Example 9;

FIG. 35B is an enlarged plan view of the facing portion (region B shown by a broken line in the figure) of the control wiring line for inspection and the alignment mark shown in FIG. 35A;

FIG. 35C is a sectional view schematically showing a sectional structure at a time when the control wiring line for inspection and the alignment mark shown in FIG. 35B are cut along a line B-B′;

FIG. 36 is a plan view schematically showing an arrangement example in which a first inspection wiring portion faces a second inspection wiring portion in Embodiment 7;

FIG. 37 is a plan view schematically showing an arrangement example in which the first inspection wiring portion faces the second inspection wiring portion in Embodiment 7;

FIG. 38 is a plan view schematically showing an arrangement example in which the first inspection wiring portion faces the second inspection wiring portion in Embodiment 7;

FIG. 39A is a plan view schematically showing an arrangement in which the first inspection wiring portion faces the second inspection wiring portion in Example 10;

FIG. 39B is an enlarged plan view of a facing portion (region B shown by a broken line in the figure) of the first and second inspection wiring portions shown in FIG. 39A; and

FIG. 39C is a sectional view schematically showing a sectional structure at a time when the first and second inspection wiring portions shown in FIG. 39B are cut along a line B-B′.

### DETAILED DESCRIPTION OF THE INVENTION

A display device will now be described with reference to the accompanying drawings according to one embodiment of the present invention.

### FIRST EMBODIMENT

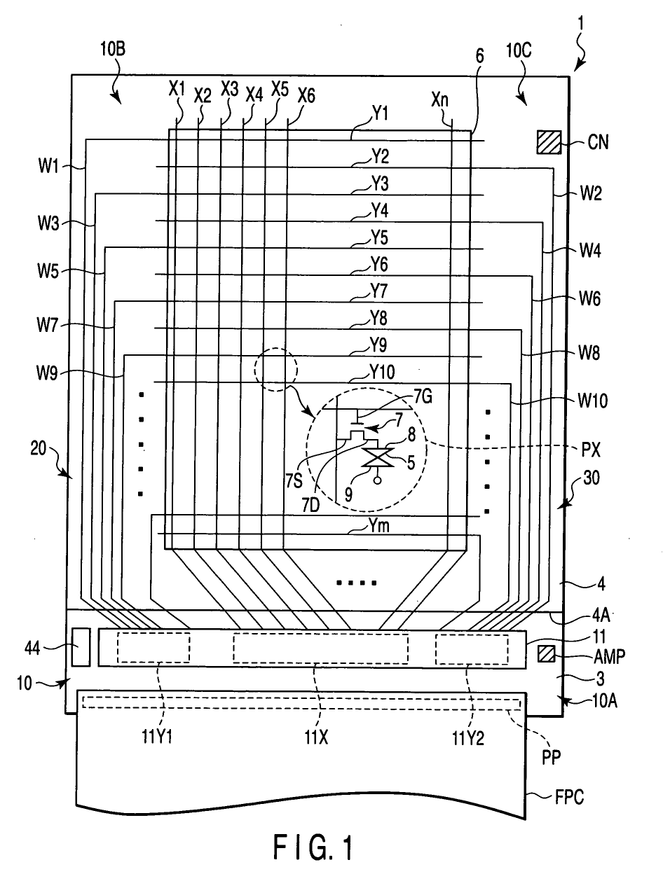

As is shown in FIG. 1, a liquid crystal display device, which is an example of a display device according to a first embodiment, includes a substantially rectangular, planar liquid crystal display panel 1. The liquid crystal display panel 1 is constituted of a pair of substrates, that is, an array substrate 3 and a counter-substrate 4, and a liquid crystal layer 5 that is interposed as an optical modulation layer between the pair of substrates. The liquid crystal display panel 1 includes a substantially rectangular effective display section 6 that displays an image. The effective display section 6 is composed of a plurality of display pixels PX that are arranged in a matrix.

The array substrate 3 includes, in the effective display section 6, a plurality of scan lines Y (1, 2, 3, . . . , m) that extend in a row direction of the display pixels PX, a plurality of signal lines X (1, 2, 3, . . . , n) that extend in a column direction of the display pixels PX, switch elements 7 that are arranged for the respective display pixels PX near intersections between the scan lines Y and the signal lines X, and pixel electrodes 8 that are connected to the switch elements 7.

The switch element 7 is formed of, e.g., a thin-film transistor (TFT). The switch element 7 has a gate electrode 7G that is electrically connected to the associated scan line Y (or formed integral with the scan line). The switch element 7 has a source electrode 7S that is electrically connected to the associated signal line X (or formed integral with the signal line). The switch element 7 has a drain electrode 7D that is electrically connected to the pixel electrode 8 of the associated display pixel PX.

The counter-substrate 4 includes a counter-electrode 9 that is common to all the display pixels PX in the effective display section 6. The array substrate 3 and the counter-substrate 4 are disposed such that the pixel electrode 8 are opposed to the counter-electrode 9, and a gap is provided therebetween. The liquid crystal layer 5 is formed of a liquid crystal composition that is sealed in the gap between the array substrate 3 and the counter-substrate 4.

In the liquid crystal display panel 1 of such a transmission type that backlight from a backlight unit is selectively transmitted to thereby display an image, an optical film such as a deflection plate is mounted on outer surfaces of the array substrate 3 and the counter-substrate 4. In the liquid crystal display panel 1 of such a reflection type that outside light is selectively reflected to thereby display the image, an optical film such as the deflection plate is mounted on the outer surface of the counter-substrate 4.

In a color display type liquid crystal display device, the liquid crystal display panel 1 includes a plurality of kinds of display pixels, for instance, a red pixel that displays red (R), a green pixel that displays green (G), and a blue pixel that displays blue (B). Specifically, the red pixel includes a red color filter that passes light with a principal wavelength of red. The green pixel includes a green color filter that passes light with a principal wavelength of green. The blue pixel includes a blue color filter that passes light with a principal wavelength of blue. These color filters are disposed on a major surface of the array substrate 3 or the counter-substrate 4.

The liquid crystal display panel 1 includes a driving IC chip 11 that is disposed on a peripheral part 10 on the outside of the effective display section 6. In the example shown in FIG. 1, the driving IC chip 11 is disposed on an extension part 10A of the array substrate 3, which extends outward beyond an end portion 4A of the counter-substrate 4. The liquid crystal display panel 1 includes a pad portion PP having a plurality of connection pads connectable to a flexible wiring board FPC having a driving circuit that supplies driving signals to the effective display section 6. In the example shown in FIG. 1, the pad portion PP is formed on the extension part 10A in the same manner as in the driving IC chip 11.

The driving IC chip 11 includes a signal line driving section 11X that supplies driving signals (video signals) to the signal lines X, and a scan line driving section 11Y that supplies driving signals (scan signals) to the scan lines Y.

The scan line driving section 11Y includes a first driving unit 11Y1 that outputs driving signals to odd-number-th scan lines Y (1, 3, 5, . . . ), and a second driving unit 11Y2 that outputs driving signals to even-number-th scan lines Y (2, 4, 6, . . . ). The first driving unit 11Y1 and the second driving unit 11Y2 are disposed on opposite sides of the signal line driving section 11X so as to sandwich the signal line driving section 11X.

To be more specific, the first driving unit 11Y1 is electrically connected to the odd-number-th scan lines Y (1, 3, 5, . . . ) via a first wiring line group 20 that is disposed on one end side 10B of the peripheral part 10. The first wiring line group 20 is constituted of wiring lines W (1, 3, 5, . . . ) that are connected to the odd-number-th scan lines Y (1, 3, 5, . . . ). Driving signals that are output from the first driving unit 11Y1 are supplied via the wiring lines W (1, 3, 5, . . . ) to the associated odd-number-th scan lines Y (1, 3, 5, . . . ), thereby turning on/off the display pixels PX on the odd-number-th rows. That is, the switch element 7 that is included in each odd-number-th display pixel PX is ON/OFF controlled on the basis of the driving signal that is supplied from the associated scan line Y.

The second driving unit 11Y2 is electrically connected to the even-number-th scan lines Y (2, 4, 6, . . . ) via a second wiring line group 30 that is disposed on the other end side 10C of the peripheral part 10. The second wiring line group 30 is constituted of wiring lines W (2, 4, 6, . . . ) that are connected to the even-number-th scan lines Y (2, 4, 6, . . . ). Driving signals that are output from the second driving unit 11Y2 are supplied via the wiring lines W (2, 4, 6, . . . ) to the associated even-number-th scan lines Y (2, 4, 6, . . . ), thereby turning on/off the display pixels PX on the even-number-th rows.

Moreover, the signal line driving section 11X is electrically connected to the respective signal lines X (1, 2, 3, . . . ). The switch element 7 included in each display pixel PX of each column writes the video signal supplied from the associated signal line X into the pixel electrode 8 at a timing at which the element is turned on.

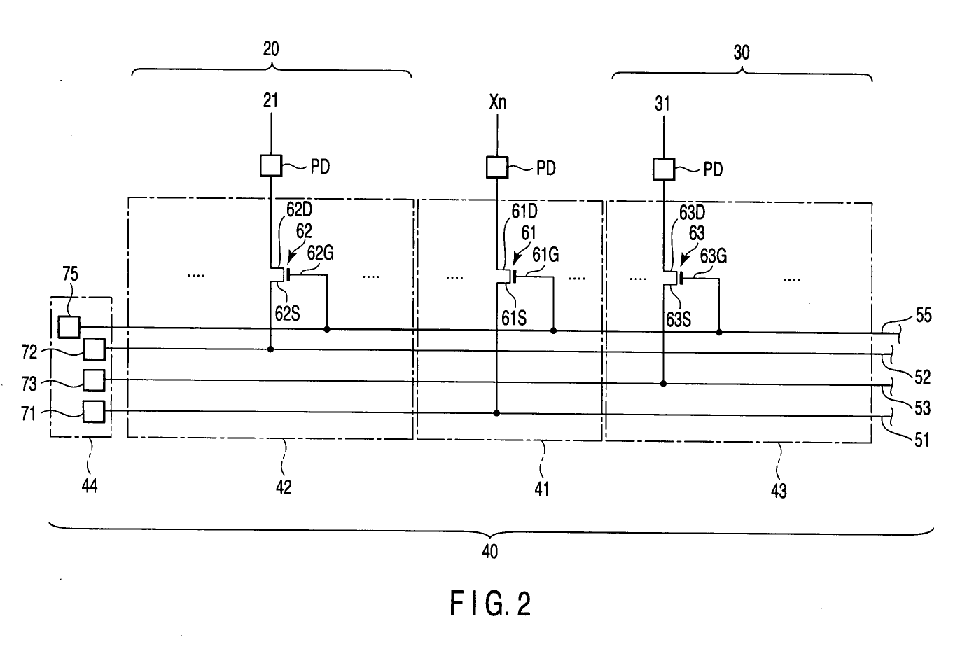

As is shown in FIG. 2, the array substrate 3 includes an inspection wiring line section 40 for inspecting qualities in the effective display section 6, such as a wiring defect between the lines of the first wiring line group 20 and a wiring defect between the lines of the second wiring line group 30 on the peripheral part 10, and a wiring defect in the effective display section 6, or a display quality of the display pixel PX. The inspection wiring line section 40 includes a signal line inspection section 41 that is provided in association with the signal line driving section 11X, a first scan line inspection section 42 that is provided in association with the first driving unit 11Y1 of the scan line driving section 11Y, a second scan line inspection section 43 that is provided in association with the second driving unit 11Y2 of the scan line driving section 11Y, and a pad section 44 for inputting various inspecting signals to the respective inspection sections 41, 42, and 43.

The signal line inspection section 41 includes a signal line inspection driving wiring line 51 to which a driving signal for inspection is supplied in inspecting the effective display section 6 and which is connected to each signal line X. This signal line inspection section 41 also includes switch elements 61 between the respective signal lines X (1, 2, . . . , n) and the signal line inspection driving wiring line 51. Furthermore, the signal line inspection section 41 includes an inspection control wiring line 55. That is, the signal line inspection driving wiring line 51 and the inspection control wiring line 55 function as inspection wiring lines to which signals for inspection are supplied in inspecting the effective display section 6 in the signal line inspection section 41.

Each of the switch elements 61 is composed of a thin-film transistor. That is, a gate electrode 61G of the switch element 61 is electrically connected to a common switching signal line 54. A source electrode 61S of the switch element 61 is electrically connected to the associated signal line inspection driving wiring line 51. Furthermore, a drain electrode 61D of each switch element 61 is electrically connected to the associated signal line X.

The first scan line inspection section 42 includes a first inspection driving wiring line 52 to which a driving signal for inspection is supplied in inspecting the effective display section 6 and which is connected to wiring lines 21 of the first wiring line group 20, fir instance, wiring lines W1, W3, W5, . . . . The first scan line inspection section 42 includes switch elements 62 between the respective wiring lines 21 and the first inspection driving wiring line 52. Furthermore, the first scan line inspection section 42 has the inspection control wiring line 55 to which a control signal for inspection is supplied to control ON/OFF of the switch element 62 in inspecting the effective display section 6. The inspection control wiring line 55 is common to the signal line inspection section 41. That is, the first inspection driving wiring line 52 and the inspection control wiring line 55 function as wiring lines for inspection, to which signals for inspection are supplied in inspecting the effective display section 6 in the first scan line inspection section 42.

The switch elements 62 are composed of thin-film transistors. A gate electrode 62G of each switch element 62 is electrically connected to the inspection control wiring line 55. A source electrode 62S of the switch element 62 is electrically connected to the first inspection driving wiring line 52. Furthermore, a drain electrode 62D of each switch element 62 is electrically connected to the associated wiring line 21.

The second scan line inspection section 43 includes a second inspection driving wiring line 53 to which a driving signal for inspection is supplied in inspecting the effective display section 6 and which is connected to wiring lines 31 of the second wiring line group 30, for instance, wiring lines W2, W4, W6 . . . The second scan line inspection section 43 includes switch elements 63 between the wiring lines 31 and the second inspection driving wiring line 53. Furthermore, the second scan line inspection section 43 has the inspection control wiring line 55 to which a control signal for inspection is supplied to control ON/OFF of the switch element 63 in inspecting the effective display section 6. This inspection control wiring line 55 is common to the signal line inspection section 41. That is, the second inspection driving wiring line 53 and the inspection control wiring line 55 function as wiring lines for inspection, to which signals for inspection are supplied in inspecting the effective display section 6 in the second scan line inspection section 43.

The switch elements 63 are composed of thin-film transistors. A gate electrode 63G of each switch element 63 is electrically connected to the inspection control wiring line 55. A source electrode 63S of the switch element 63 is electrically connected to the second inspection driving wiring line 53. Furthermore, a drain electrode 63D of each switch element 63 is electrically connected to the associated wiring line 31.

The pad section 44 includes an input pad 71 which enables input of an inspection driving signal to one end portion of the signal line inspection driving wiring line 51, an input pad 72 which enables input of an inspection driving signal to one end portion of the first inspection driving wiring line 52, an input pad 73 which enables input of an inspection driving signal to one end portion of the second inspection driving wiring line 53, and an input pad 75 which enables input of an inspection control signal to one end portion of the inspection control wiring line 55.

The driving signal that is input from the input pad 71 is an inspection signal that is written in the pixel electrode 8 of each display pixel PX at a stage of inspection. The driving signals that are input from the input pads 72 and 73 are inspection signals for ON/OFF controlling the switching elements 7 of the respective display pixels PX at the stage of inspection. The control signal that is input from the input pad 75 is an inspection signal for ON/OFF controlling the switch element 61 of the signal line inspection section 41, the switch element 62 of the first scan line inspection section 42, and the switch element 63 of the second scan line inspection section 43 at the stage of inspection.

The respective signal lines X (1, 2, . . . , n), the respective wiring lines 21 of the first wiring line group 20, and the respective wiring line 31 of the second wiring line group 30 include connection pads PD at their intermediate portions, which enable connection to the driving IC chip 11.

Moreover, as is shown in FIG. 1, the array substrate 3 includes an alignment mark AMP required for positioning of the liquid crystal display panel 1 and components in mounting the component on the liquid crystal display panel 1. Examples of the component to be mounted on the liquid crystal display panel 1 include a polarization plate, a driving IC chip, and a flexible wiring board. The alignment mark AMP is, for example, a metal film formed in the same step as a step of forming scan lines, signal lines, pixel electrodes and the like. In the example shown in FIG. 1, this alignment mark AMP is disposed in the extension part 10A of the array substrate 3, but the present invention is not limited to this example, and the mark may be disposed in any position on the array substrate 3. A plurality of alignment marks may be disposed on the array substrate 3. Here, the alignment mark AMP may be a mark in which identification information such as a lot number or a manufacturing history is engraved.

Moreover, as shown in FIG. 1, the liquid crystal display panel 1 is provided with a connecting portion CN for supplying a potential that is common to all the display pixels PX to the counter-electrode 9 from an array substrate 3 side. In the example shown in FIG. 1, the connecting portion CN is disposed in the outer peripheral part 10 of the liquid crystal display panel 1, but the present invention is not limited to this example, and the portion may be disposed in any position where the array substrate 3 faces the counter-substrate 4 in the liquid crystal display panel 1, and a plurality of connecting portions may be disposed in the liquid crystal display panel 1.

According to the liquid crystal display constituted as described above, it is possible to exactly detect wiring defects on the panel, such as short-circuit between the wiring lines of the first wiring line group or line breakage of each wiring line, short-circuit between the wiring lines of the second wiring line group or line breakage of each wiring line, and a wiring defect in the effective display section 6.

Moreover, the signal line inspection section 41, the first scan line inspection section 42, and the second scan line inspection section 43 are disposed on the extension part 10A of the array substrate 3 at a position corresponding to a region where the driving IC chip 11 is disposed. Needless to say, the signal line inspection driving wiring line 51, the first inspection driving wiring line 52, the second inspection driving wiring line 53, and the inspection control wiring line 55 are disposed on the extension part 10A corresponding to the region where the driving IC chip 11 is disposed. These wiring lines for inspection 51, 52, 53, and 55 extend along a longitudinal direction of the driving IC chip 11. That is, these wiring lines for inspection 51, 52, 53, and 55 overlap the driving IC chip 11 when the driving IC chip 11 is mounted. In short, the inspection wiring lines can be disposed on the array substrate without increasing outer dimensions.

Furthermore, each connection pad PD connectable to the driving IC chip 11 is disposed between the effective display section 6 and the inspection section 40. Therefore, a wiring line path in which an inspection signal for performing the inspection of the frequency in the effective display section 6 is supplied via the inspection section 40 agrees with that in which a driving signal (video signal and scan signal) for displaying an image in the effective display section 6 is supplied from the driving IC chip 11. Therefore, when the driving IC chip 11 judged to be normal is mounted on the liquid crystal display panel 1 judged to be satisfactory by the inspection via the inspection section 40, there can be provided the liquid crystal display having a high reliability.

<<Accumulation of Electric Charges>>

In the display device constituted as described above, electric charges are easily accumulated in a wiring line having a comparatively installation area in a manufacturing process. Especially, the signal line inspection driving wiring line 51, the first inspection driving wiring line 52, the second inspection driving wiring line 53, the inspection control wiring line 55, the common wiring line for supplying to the counter-electrode 9 or the like the potential that is common to a plurality of display pixels PX is an inspection wiring line to which an inspection signal is supplied in an inspection step of inspecting the effective display section 6. Since the inspection wiring line has a broad line width and a long wiring length, the installation area is large, and the electric charges are easily accumulated. The accumulated electric charges are easily concentrated on a terminal end portion or a bent portion of the wiring line, and this causes a static discharge between the wiring line and another adjacent conductive layer (wiring line, electrode or the like). Such static discharge might cause the short-circuit between the adjacent wiring lines whose insulated states should be maintained, or the line breakage with respect to the adjacent wiring line.

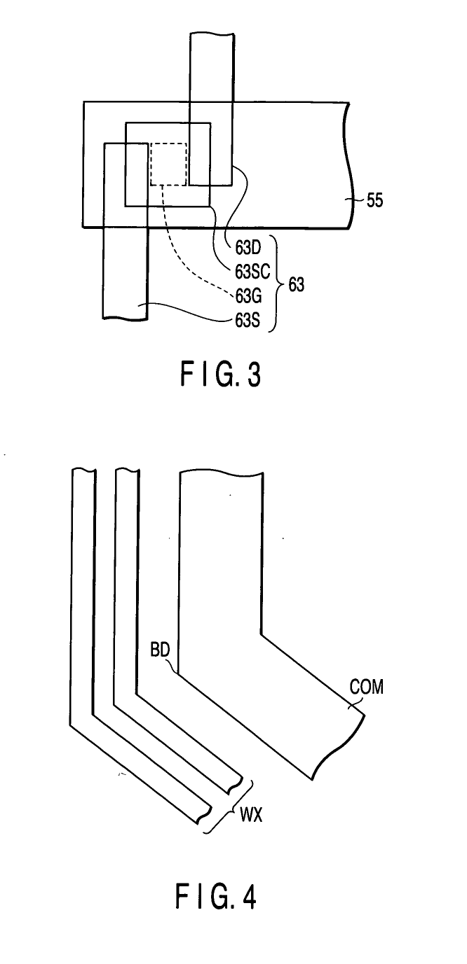

For example, as shown in FIG. 3, a semiconductor layer 63SC is electrically connected to the source electrode 63S and the drain electrode 63D in the switch element 63 positioned in the vicinity of the end portion of the inspection control wiring line 55. When the electric charges are accumulated in the inspection control wiring line 55 in this constitution, the electric charges are easily concentrated on the gate electrode 63G of the switch element 63 disposed in the vicinity of the terminal end portion, the discharge is caused, and the short-circuit might be caused between the gate electrode 63G and the source electrode 63S or between the gate electrode 63G and the drain electrode 63D.

Moreover, as shown in FIG. 4, when the electric charges are accumulated in a common wiring line COM, the electric charges are easily concentrated on a bent portion BD of the line, the discharge is caused, and the short-circuit might be caused between a wiring line WX to which another potential is supplied and the bent portion BD. When the discharge has a large scale, the line breakage of the adjacent wiring line WX might be caused. Since a wiring defect such as the short-circuit or the line breakage causes a pixel defect in the completed liquid crystal display panel, a manufacturing yield is lowered.

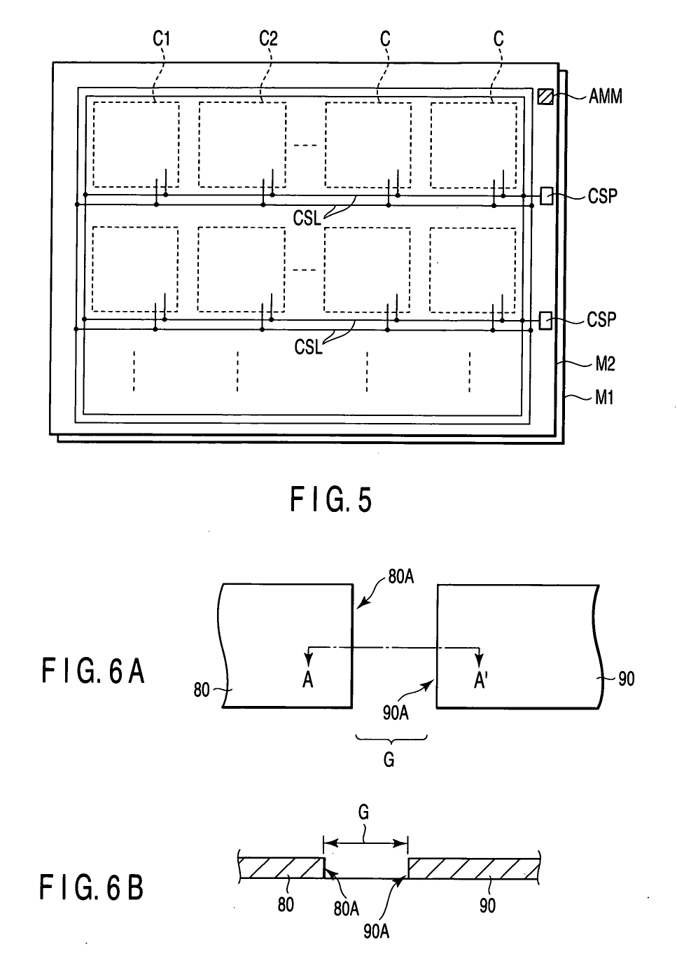

Furthermore, a plurality of display devices constituted as described above can be simultaneously manufactured using a mother substrate for the display device. That is, as shown in FIG. 5, the display device mother substrate for manufacturing the liquid crystal display is constituted of a first mother substrate M1 for the array substrate, and a second mother substrate M2 for the counter-substrate. Each of these first and second mother substrates M1 and M2 has a plurality of cell regions C1, C2 . . . which are scribed to constitute the individual liquid crystal display panels 1.

That is, each of the first and second mother substrates M1 and M2 includes the effective display section 6 in each cell region C, and the substrates are laminated via a sealing material disposed in such a manner as to surround each effective display section 6. These first and second mother substrates M1 and M2 can hold the liquid crystal layer 5 surrounded with the sealing material in each cell region C. When the first mother substrate M1 constituted in this manner is scribed along each cell region C, the array substrate 3 of each liquid crystal display panel 1 is formed. When the second mother substrate M2 is scribed along each cell region C, the counter-substrate 4 of each liquid crystal display panel 1 is formed.

On the other hand, the first mother substrate M1 has a common signal line CSL which is disposed outside the cell region and which supplies a common signal into each cell region. Various types of inspection signals are supplied to this common signal line CSL, when the inspection of the quality is performed in each cell region before the scribing. This common signal line CSL is formed into, for example, a loop shape, and a part of the loop shape is connected to an inspection pad CSP.

Moreover, the first mother substrate M1 is provided with an alignment mark AMM which is disposed outside the cell region and which is required for positioning of a display device mother substrate in the manufacturing process. That is, this alignment mark AMM is utilized in the positioning between the first mother substrate M1 and various types of manufacturing devices when various types of conductive layers and insulating layers are formed on the first mother substrate M1, the positioning between the first mother substrate M1 and a mask for each type of patterning and the like. The alignment mark AMM on the first mother substrate M1 is also utilized in the positioning between the first and second mother substrates M1 and M2 during the laminating of the second mother substrate M2.

This alignment mark AMM is formed of a metal film in the same manner as in the alignment mark AMP disposed in the cell region shown in FIG. 1. In the example shown in FIG. 5, this alignment mark AMM is disposed in a peripheral region of the first mother substrate M1, but the present invention is not limited to this example, and the mark may be disposed in any position on the first mother substrate M1, or a plurality of marks may be disposed on the first mother substrate M1. Here, the alignment mark AMM may be a mark in which identification information such as the lot number or the manufacturing history is carved.

Even in such mother substrate for the display device, the electric charges are easily accumulated in the wiring line having a comparatively large installation area in the manufacturing process. Since the electric charges are easily accumulated especially in the inspection wiring line of each cell region C, there is a possibility that wiring defect such as the short-circuit or the line breakage is generated in the same manner as described with reference to FIGS. 3 and 4.

<<Constitution Example>>

According to the present embodiment, the display device has a conductive layer 90 disposed in such a manner as to face an inspection wiring line 80 at a predetermined interval. This conductive layer 90 has a discharge inducing portion 90A which faces the inspection wiring line 80 and which induces discharge of the electric charges accumulated in the inspection wiring line 80. That is, the discharge inducing portion 90A corresponds to a portion of the conductive layer 90 that faces the inspection wiring line 80. In the inspection wiring line 80, a facing portion 80A that faces the discharge inducing portion 90A may be an intermediate or an end portion of the inspection wiring line 80. The discharge inducing portion 90A is preferably disposed in such a manner as to face the end portion of the inspection wiring line 80 on which the electric charges are especially easily concentrated on the inspection wiring line 80 with a predetermined interval.

Layout examples of the inspection wiring line 80 and the conductive layer 90 will be described hereinafter.

In an example shown in FIGS. 6A and 6B, the conductive layer 90 is disposed in such a manner as to face the inspection wiring line 80 at a predetermined interval G in the same layer as that of the inspection wiring line 80. Since this conductive layer 90 is disposed in the same layer as that of the inspection wiring line 80, the layer can be formed in the same step as a step of forming the inspection wiring line 80 using the same material as that of the inspection wiring line. Therefore, a separate step of forming the conductive layer 90 is not required, and increase of manufacturing costs or large deterioration of the manufacturing yield is not caused.

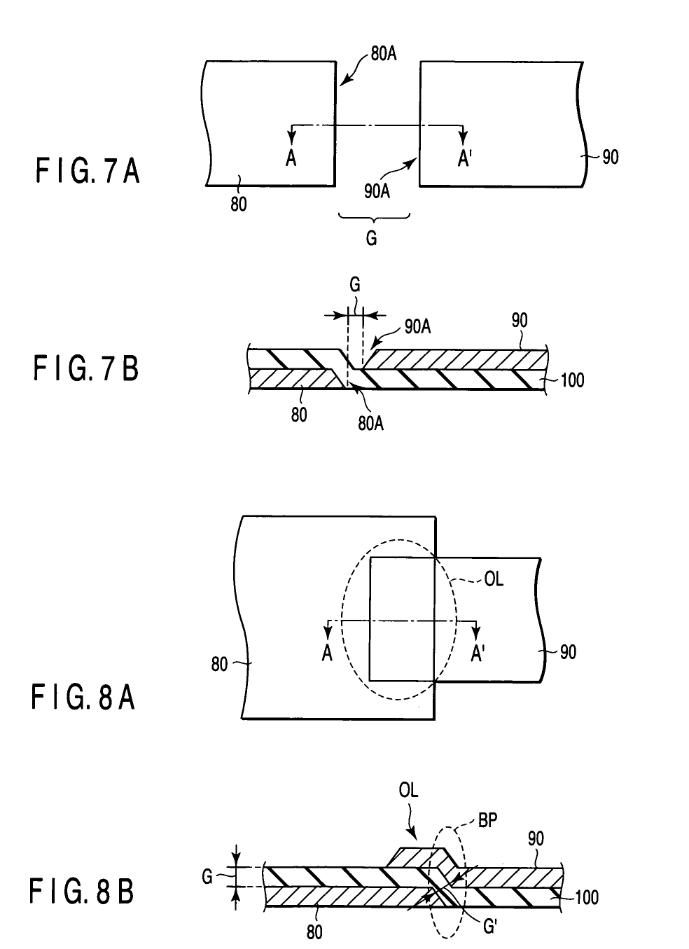

In an example shown in FIGS. 7A and 7B, a conductive layer 90 is disposed in such a manner as to face an inspection wiring line 80 at a predetermined interval G in a layer different from that of the inspection wiring line 80 via an insulating layer 100. Here, as shown in especially FIG. 7A, the conductive layer 90 and the inspection wiring line 80 are disposed lest they are superimposed on each other in a plane of a substrate (i.e., array substrate 3) in which they are disposed (i.e., the interval G between the conductive layer 90 and the inspection wiring line 80 is not zero in the plane of the array substrate 3). It is to be noted that in the example shown in FIG. 7B, the inspection wiring line 80 is disposed in a lower layer of the insulating layer 100, and the conductive layer 90 is disposed in an upper layer of the insulating layer 100, but the present invention is not limited to this example, and, needless to say, the inspection wiring line 80 may be disposed in the upper layer of the insulating layer 100, and the conductive layer 90 may be disposed in the lower layer of the insulating layer 100.

In an example shown in FIGS. 8A and 8B, a conductive layer 90 is disposed in a layer different from that of an inspection wiring line 80 via an insulating layer 100. In addition, at least a part of the conductive layer is superimposed on the inspection wiring line 80 via the insulating layer 100. That is, as shown in FIG. 8A, the conductive layer 90 is superimposed on the inspection wiring line 80 in a plane of a substrate (i.e., array substrate 3) on which they are disposed, and the conductive layer is disposed in such a manner as to face the inspection wiring line via the insulating layer 100 which is interposed between them. It is to be noted that in the example shown in FIG. 8B, the inspection wiring line 80 is disposed in a lower layer of the insulating layer 100, and the conductive layer 90 is disposed in an upper layer of the insulating layer 100, but the present invention is not limited to this example, and, needless to say, the inspection wiring line 80 may be disposed in the upper layer of the insulating layer 100, and the conductive layer 90 may be disposed in the lower layer of the insulating layer 100. In the example shown in FIG. 8B, the inspection wiring line 80 is formed to be broader than the conductive layer 90, but the present invention is not limited to this example, and, needless to say, the conductive layer 90 may be formed to be broader than the inspection wiring line 80.

The conductive layer 90 described in these examples induces the discharge of the electric charges concentrated on the inspection wiring line 80. Even if the discharge occurs (i.e., the short-circuit or the line breakage occurs as a result of the discharge), the conductive layer does not influence the completed liquid crystal display panel. For example, the conductive layer 90 may be a conductive member disposed (i.e., electrically floated) in an insular shape facing the inspection wiring line 80, a wiring line for supplying a predetermined signal (or a predetermined voltage) or the like. In a case where the conductive layer 90 is the wiring line, it is preferable to utilize as the conductive layer 90 a wiring line into which a signal contributing to the display is not input in the completed liquid crystal display panel. That is, the wiring line to be utilized as the conductive layer 90 is preferably a wiring line into which any signal is not input, or such a signal as to fix the respective switch elements 61, 62, and 63 disposed in the inspection section 40 in off-states is input after mounting the flexible wiring board FPC, the driving IC chip or the like. When such wiring line or island-shaped conductive member is utilized as the conductive layer 90, a display quality level is not influenced in the completed liquid crystal display panel even if the layer short-circuits the inspection wiring line 80. In a case where the conductive layer 90 is the wiring line, when the discharge can be suppressed to such a small scale as to release the electric charges of the inspection wiring line 80 without causing the short-circuit or the line breakage, the wiring line into which such a signal as to contribute to the display may be utilized as the conductive layer 90.

In the example shown in FIGS. 7A and 7B or 8A and 8B, the conductive layer 90 can be formed using the same material and step as those of the electrode or the wiring line to be formed in a layer different from that of the inspection wiring line 80 which is to be disposed in such a manner as to face the conductive layer. For example, when the inspection wiring line 80 is the inspection control wiring line 55, the conductive layer 90 can be formed using the same material and step as those of the source electrode or the drain electrode to be formed in a layer different from that of the inspection wiring line 80 via the insulating layer 100. Therefore, a separate step of forming the conductive layer 90 is not required, and the increase of the manufacturing cost or the large deterioration of the manufacturing yield is not caused.

The predetermined interval G between the conductive layer 90 and the inspection wiring line 80 is set to such a distance as to induce the discharge, and is preferably as small as possible. However, when they short-circuit (the interval is set to zero), a resistance becomes excessively small, and energy of electrostatic discharge damage cannot be consumed. Therefore, the interval G is preferably set to such a distance that they are electrically insulated.

In the example shown in FIGS. 6A and 6B, or 7A and 7B, the predetermined interval G corresponds to a distance between the conductive layer 90 and the inspection wiring line 80 in the plane of the array substrate 3 in which they are disposed. In the example shown in FIGS. 8A and 8B, since the conductive layer 90 is superimposed on the inspection wiring line 80 via the insulating layer 100, the interval between the layer and the line substantially corresponds to a film thickness G of the insulating layer 100. As the case may be, a thickness G′ of the insulating layer 100 interposed between the upper and lower layers is sometimes smaller than the substantial film thickness G in a stepped portion BP in which the upper layer (here, the conductive layer 90) rides on the lower layer (here, the inspection wiring line 80). In this case, the interval between the conductive layer 90 and the inspection wiring line 80 corresponds to the thickness G′ of the insulating layer 100 in the stepped portion BP. In either case, the interval between the conductive layer 90 and the inspection wiring line 80 is defined to correspond to the shortest distance between them in a section of the array substrate 3 where they are disposed.

In a case where the conductive layer 90 and the inspection wiring line 80 are disposed in the same layer as in the example shown in FIGS. 6A and 6B, there is a certain degree of limit to the interval G between the layer and the line owing to a resolution limit in a step of patterning them. On the other hand, in a case where the conductive layer 90 and the inspection wiring line 80 are disposed in different layers as in the example shown in FIGS. 7A and 7B, or 8A and 8B, even when a restriction on the patterning step is removed, and the conductive layer is superimposed on the inspection wiring line in the plane of the array substrate 3, it is possible to form a state in which they are electrically insulated via the insulating layer 100. That is, as compared with the case where the inspection wiring line 80 and the conductive layer 90 are disposed in the same layer, the interval between the conductive layer 90 and the inspection wiring line 80 can be reduced, and the discharge can be easily induced. In a case where the conductive layer 90 is superimposed on the inspection wiring line 80 via the insulating layer 100, the interval between them corresponds to a minimum distance in the section. Therefore, it is possible to control the interval between them depending on the film thickness of the insulating layer 100. The insulating layer 100 can be set to a film thickness of the order of 0.1 μm. As compared with a case where the predetermined interval is to be formed in the array substrate plane, a smaller interval can be formed, and the discharge can be more easily induced.

Moreover, in a case where the inspection wiring line 80 and the conductive layer 90 are formed at a small interval in the same layer as in the example shown in FIGS. 6A and 6B, an exposure mask required for the patterning step needs to be prepared with a high precision, and the exposure mask needs to be positioned with a high precision in the patterning step. On the other hand, when the inspection wiring line 80 and the conductive layer 90 are formed in the different layers as in the example shown in FIGS. 7A and 7B, or 8A and 8B, it is not necessary to satisfy such requirement, and it is possible to reduce the manufacturing cost and enhance the manufacturing yield.

In the above-described example, shapes of the portion of the conductive layer 90 facing the inspection wiring line 80, that is, the discharge inducing portion 90A, and the portion 80A of the inspection wiring line 80 facing the conductive layer 90 are not limited to rectangular shapes. That is, at least one of the discharge inducing portion 90A and the facing portion 80A preferably has a shape (i.e., sharp shape) on which the electric charges are easily concentrated. That is, the facing portion 80A has at least one polygonal salient portion that protrudes toward the conductive layer 90. The discharge inducing portion 90A has at least one polygonal salient portion that protrudes toward the inspection wiring line 80. At least one vertex of the salient portion of the discharge inducing portion 90A faces the inspection wiring line 80 at a predetermined interval. At least one vertex of the salient portion of the facing portion 80A faces the conductive layer 90 at a predetermined interval.

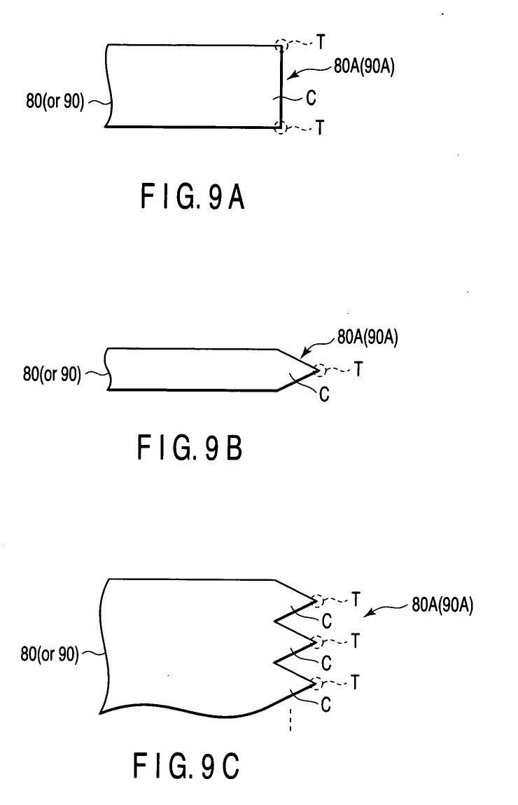

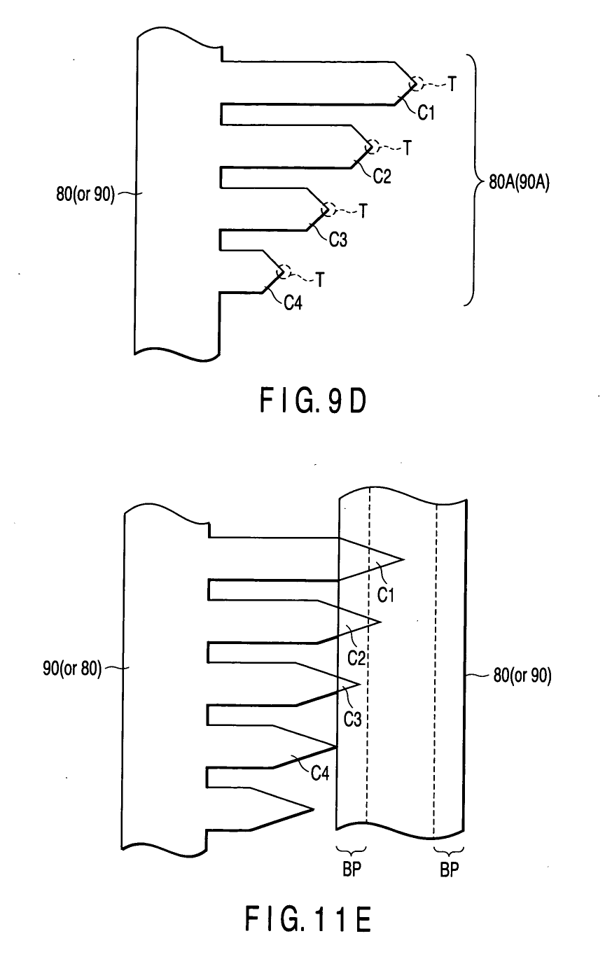

To be more specific, as shown in FIG. 9A, at least one of the facing portion 80A and the discharge inducing portion 90A may have a shape including one quadrangular salient portion C and two vertexes T. As shown in FIG. 9B, at least one of the facing portion 80A and the discharge inducing portion 90A may have a shape including one triangular salient portion C and one vertex T. Furthermore, at least one of the facing portion 80A and the discharge inducing portion 90A may have a shape including a plurality of (n) triangular salient portions C, and a plurality of (n) vertexes T. That is, an example shown in FIG. 9C indicates a shape (i.e., shape having a plurality of vertexes T) having saw-tooth-like salient portions C constituted of continuous triangular shapes. In the examples shown in FIGS. 9B and 9C, the vertex T can be formed to be sharper, and an electric field is easily concentrated as compared with the example shown in FIG. 9A.

Moreover, as shown in FIG. 9D, at least one of the facing portion 80A and the discharge inducing portion 90A may have a shape including a plurality of salient portions C1, C2, C3 . . . having gradually different lengths. In the example shown in FIG. 9D, an interval (or an overlap amount) between such shape and a facing portion can be varied for each salient portion.

Furthermore, although not shown, at least one of the facing portion 80A and the discharge inducing portion 90A may have a shape including n m-angles salient portions C and a plurality of vertexes, but the shape of the vertex T is preferably sharper in consideration of ease of concentration of the electric field. It is to be noted that the plurality of salient portions C and vertexes T do not have to be aligned in a row, and may be directed in any direction in the substrate plane.

In a case where the facing portion 80A and the discharge inducing portion 90A have the salient portions C as shown in FIGS. 9A to 9C, the predetermined interval G may be defined as a distance between a tip (i.e., the vertex T) of the salient portion C and the portion facing the tip.

A pattern combination at a time when the facing portion 80A of the inspection wiring line 80 is allowed to face the discharge inducing portion 90A of the conductive layer 90 is not limited to a combination of the rectangular facing portions shown in FIGS. 6A and 7A.

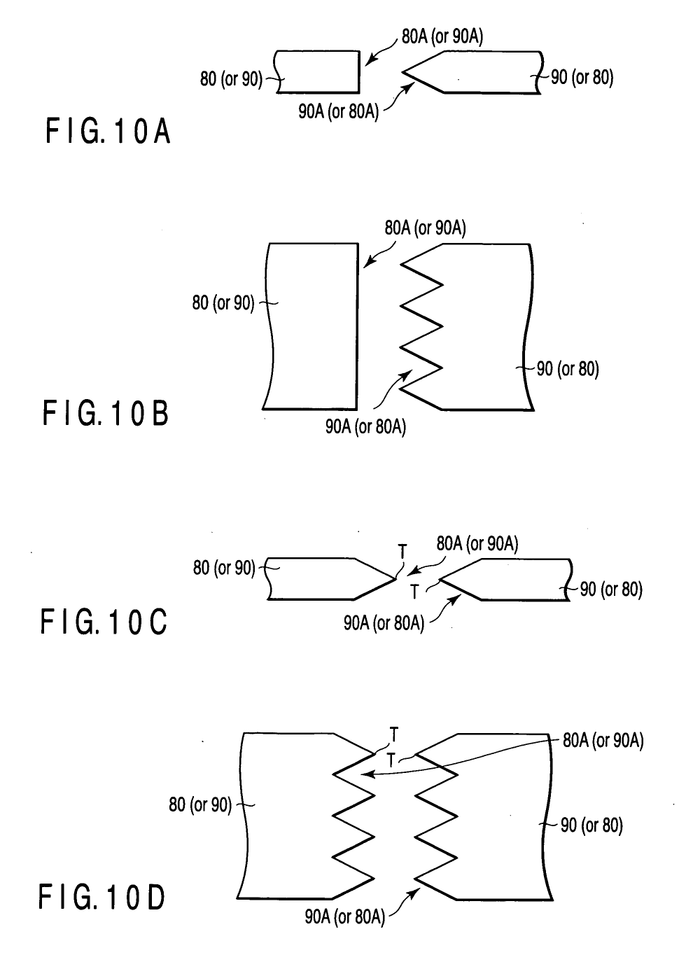

That is, when the inspection wiring line 80 is allowed to face the conductive layer 90 as shown in FIG. 10A, one rectangular facing portion may be combined with the other facing portion including a triangular salient portion. When the inspection wiring line 80 is allowed to face the conductive layer 90 as shown in FIG. 10B, one rectangular facing portion may be combined with the other facing portion including the saw-teeth-shaped salient portion. Furthermore, when the inspection wiring line 80 is allowed to face the conductive layer 90 as shown in FIG. 10C, one triangular facing portion may be combined with the other facing portion including the triangular salient portion. In the example shown in FIG. 10C, the vertex T of one facing portion more preferably faces that of the other facing portion at the shortest distance. Furthermore, when the inspection wiring line 80 is allowed to face the conductive layer 90 as shown in FIG. 10D, one saw-teeth-shaped facing portion may be combined with the other facing portion including the saw-teeth-shaped salient portion. In the example shown in FIG. 10D, the vertex T of one facing portion more preferably faces that of the other facing portion at the shortest distance.

Moreover, when the facing portion 80A of the inspection wiring line 80 is allowed to face the discharge inducing portion 90A of the conductive layer 90, the pattern combination of an overlap portion OL where the inspection wiring line 80 overlaps with the conductive layer 90 is not limited to the combination of the rectangular facing portions shown in FIG. 8A. That is, at least one of the inspection wiring line 80 and the conductive layer 90 has at least one polygonal salient portion as a shape on which the electric charges are easily concentrated, and a part of this salient portion including at least one vertex may constitute the overlap portion OL.

In the example described above with reference to FIGS. 9B and 9C, as compared with the example shown in FIG. 9A, a length of an edge constituting the overlap portion OL can be extended, the vertex T can be formed to be sharper, and the electric field is easily concentrated.

In the inspection wiring line 80 and the conductive layer 90 shaped as described above, a part of the salient portion formed on at least one of them, including at least one vertex, may constitute the overlap portion OL. That is, the conductive layer 90 may have at least one polygonal salient portion C, and a part of the salient portion C including at least one vertex T may be disposed in such a manner as to overlap with the inspection wiring line 80. The inspection wiring line 80 may have at least one polygonal salient portion C, and a part of the salient portion C including at least one vertex T may be disposed in such a manner as to overlap with the conductive layer 90.

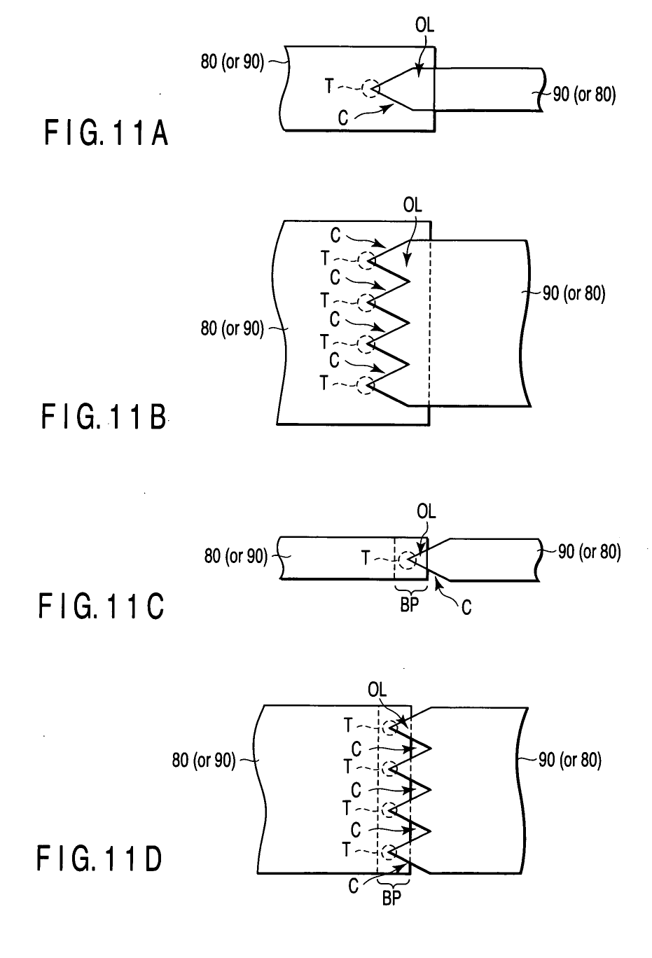

For example, as shown in FIG. 11A, in a case where the discharge inducing portion 90A of the conductive layer 90 has one triangular salient portion C, the conductive layer 90 may be disposed in such a manner that the whole salient portion C overlaps with the inspection wiring line 80. In this case, needless to say, the vertex T of the salient portion C of the conductive layer 90 overlaps with the inspection wiring line 80. Alternatively, in a case where the inspection wiring line 80 has one triangular salient portion C, the inspection wiring line 80 may be disposed in such a manner that the whole salient portion C overlaps with the discharge inducing portion 90A of the conductive layer 90. In this case, needless to say, the vertex T of the salient portion C of the inspection wiring line 80 overlaps with the conductive layer 90. When such arrangement constitutes the overlap portion OL, the inspection wiring line 80 is disposed in such a manner as to face the conductive layer 90 at an interval substantially corresponding to the film thickness of the insulating layer 100 via the vertex T on which the electric field is easily concentrated, and the discharge of the electric charges accumulated in the inspection wiring line 80 can be induced.

Moreover, when the discharge inducing portion 90A of the conductive layer 90 has a plurality of triangular salient portions C as shown in FIG. 11B, the conductive layer 90 may be disposed in such a manner that all the salient portions C overlap with the inspection wiring line 80. In this case, needless to say, the vertex T of the salient portion C of the conductive layer 90 overlaps with the inspection wiring line 80. Alternatively, when the inspection wiring line 80 has a plurality of triangular salient portions C, the inspection wiring line 80 may be disposed in such a manner that all the salient portions C overlap with the discharge inducing portion 90A of the conductive layer 90. Even in this case, needless to say, the vertex T of each salient portion C of the inspection wiring line 80 overlaps with the conductive layer 90. When such arrangement constitutes the overlap portion OL, the inspection wiring line 80 is disposed in such a manner as to face the conductive layer 90 at an interval substantially corresponding to the film thickness of the insulating layer 100 via the vertex T on which the electric field is easily concentrated, and the discharge of the electric charges accumulated in the inspection wiring line 80 can be induced.

Furthermore, when the discharge inducing portion 90A of the conductive layer 90 has one triangular salient portion C as shown in FIG. 11C, the conductive layer 90 may be disposed in such a manner that a part of the salient portion C including one vertex T overlaps with the inspection wiring line 80. In this case, especially the vertex T of the salient portion C of the conductive layer 90 is preferably positioned in the stepped portion BP where the vertex rides on the inspection wiring line 80. Alternatively, when the inspection wiring line 80 has one triangular salient portion C, the inspection wiring line 80 may be disposed in such a manner that a part of the salient portion C including one vertex T overlaps with the discharge inducing portion 90A of the conductive layer 90. Similarly in this case, the vertex T of the salient portion C of the inspection wiring line 80 is preferably positioned in the stepped portion BP where the vertex rides on the conductive layer 90. When such arrangement constitutes the overlap portion OL, the inspection wiring line 80 is disposed in such a manner as to face the conductive layer 90 at a micro interval corresponding to the thickness of the insulating layer 100 interposed between them via the vertex T on which the electric field is easily concentrated, and the discharge of the electric charges accumulated in the inspection wiring line 80 can be induced more.

In addition, when the discharge inducing portion 90A of the conductive layer 90 has a plurality of triangular salient portions C as shown in FIG. 1D, the conductive layer 90 may be disposed in such a manner that a part of each salient portion C including one vertex T overlaps with the inspection wiring line 80. In this case, especially the vertex T of the salient portion C of the conductive layer 90 is preferably positioned in the stepped portion BP where the vertex rides on the inspection wiring line 80. Alternatively, when the inspection wiring line 80 has a plurality of triangular salient portions C, the inspection wiring line 80 may be disposed in such a manner that a part of each salient portion C including one vertex T overlaps with the discharge inducing portion 90A of the conductive layer 90. Similarly in this case, the vertex T of the salient portion C of the inspection wiring line 80 is preferably positioned in the stepped portion BP where the vertex rides on the conductive layer 90. When such arrangement constitutes the overlap portion OL, the inspection wiring line 80 is disposed in such a manner as to face the conductive layer 90 at a micro interval corresponding to the thickness of the insulating layer 100 interposed between them via the vertex T on which the electric field is easily concentrated, and the discharge of the electric charges accumulated in the inspection wiring line 80 can be induced more.

Furthermore, when the discharge inducing portion 90A of the conductive layer 90 has a plurality of salient portions C1, C2 . . . as shown in FIG. 11E, the conductive layer 90 may be disposed in such a manner that a part of each salient portion including one vertex T overlaps with the inspection wiring line 80. In this case, especially the vertex T of one salient portion C (C3 in the example shown in FIG. 1E) of the conductive layer 90 is preferably positioned in the stepped portion BP where the vertex rides on the inspection wiring line 80. Alternatively, when the inspection wiring line 80 has a plurality of salient portions C1, C2, . . . , the inspection wiring line 80 may be disposed in such a manner that a part of each salient portion including one vertex T overlaps with the discharge inducing portion 90A of the conductive layer 90. Similarly in this case, the vertex T of one salient portion C of the inspection wiring line 80 is preferably positioned in the stepped portion BP where the vertex rides on the conductive layer 90. When such arrangement constitutes the overlap portion OL, the inspection wiring line 80 is disposed in such a manner as to face the conductive layer 90 at a micro interval corresponding to the thickness of the insulating layer 100 interposed between them via the vertex T on which the electric field is easily concentrated, and the discharge of the electric charges accumulated in the inspection wiring line 80 can be induced more.

The shape including a plurality of salient portions having different lengths as shown in FIG. 9D is effectively applied to a case where the inspection wiring line 80 and the conductive layer 90 are disposed in the different layers in such a manner that they partially overlap with each other. That is, an amount of the electric charges accumulated in the inspection wiring line 80 differs with various types of conditions. Therefore, an optimum distance in which the discharge is easily induced by the discharge inducing portion 90A also differs with various types of conditions. Therefore, the inspection wiring line 80 faces the conductive layer 90 on various different conditions of the distance from the discharge inducing portion 90A. Accordingly, the discharge is easily induced by the discharge inducing portion 90A regardless of the amount of the electric charges accumulated in the inspection wiring line 80.

Moreover, even if there is known such optimum interval between the inspection wiring line 80 and the conductive layer 90 as to easily induce the discharge by the discharge inducing portion 90A, the optimum interval cannot be sometimes formed depending on an alignment precision in forming the inspection wiring line 80 and the conductive layer 90, respectively, in a case where the inspection wiring line 80 and the conductive layer 90 are disposed in the different layers. Therefore, for example, when the shape including a plurality of salient portions having different lengths is applied to the discharge inducing portion 90A, any one of the salient portions can be disposed to face the inspection wiring line 80 at an optimum interval. Therefore, the discharge of the electric charges accumulated in the inspection wiring line 80 can be induced more.

It is to be noted that in the examples shown in FIGS. 11A to 11E, the salient portion C including the vertex T is disposed in the upper layer, but the present invention is not limited to this example, and, needless to say, the salient portion including the vertex T may be disposed in the lower layer. The lower layer is formed to be broader than the upper layer, but the present invention is not limited to this example, and, needless to say, the upper layer may be formed to be broader than the lower layer.

According to this constitution, the electric charges accumulated in the inspection wiring line 80 can be relieved by the discharge with respect to the conductive layer 90. Consequently, it is possible to prevent in advance undesired discharge between the inspection wiring line 80 and another adjacent conductive layer, occurrence of undesired short-circuit or line breakage attributable to this discharge or the like.

Therefore, in an inspection stage in which the inspection of the quality is performed in the effective display section 6 before mounting the flexible wiring board FPC or the driving IC chip 11, it is possible to stably inspect wiring defects of various types of wiring lines by use of the inspection section 40, defects can be prevented from being generated in the completed liquid crystal display panel, and it is possible to suppress the drop of the manufacturing yield.

### EXAMPLE 1

### Conductive Layer-Inspection Control Wiring Line; Disposed in the Same Layer

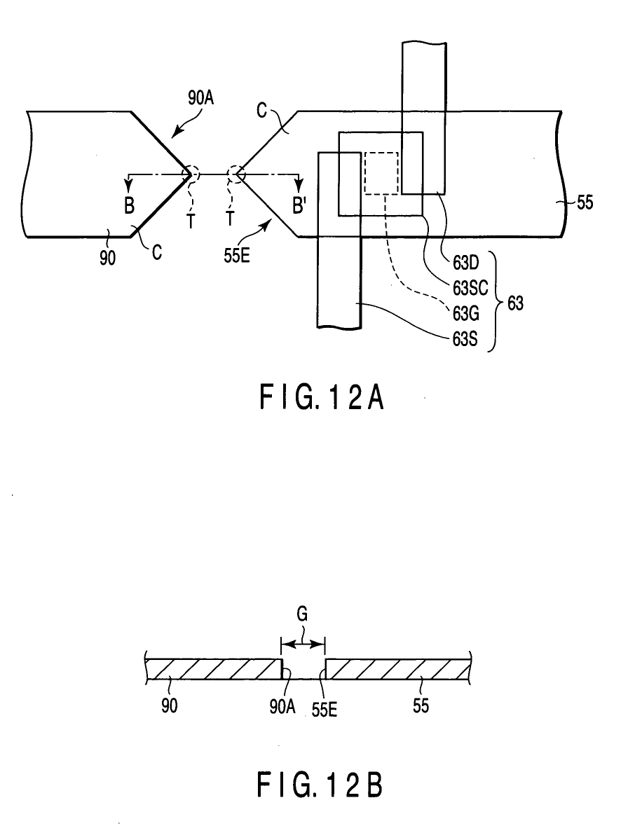

In Example 1, a constitution example will be described in which discharge is induced in an end portion 55E of an inspection control wiring line 55. As shown in FIGS. 12A and 12B, the end portion 55E of the inspection control wiring line 55 is disposed in such a manner as to face a conductive layer 90 at a predetermined interval in the same layer as that of the inspection control wiring line 55 integral with a gate electrode 63G of a switch element 63. The end portion 55E of the inspection control wiring line 55 facing the conductive layer 90 has a salient portion C protruding toward the conductive layer 90. A discharge inducing portion 90A of the conductive layer 90 facing the inspection control wiring line 55 has a salient portion C protruding toward the inspection control wiring line 55. That is, the inspection control wiring line 55 and the conductive layer 90 are disposed in such a manner that vertexes T of the salient portions C face each other at a predetermined interval G in the same layer.

According to such constitution, it is possible to relieve electric charges concentrated on the end portion 55E of the inspection control wiring line 55 by the discharge with the conductive layer 90. Consequently, it is possible to prevent in advance undesired discharge in the vicinity of the end portion of the inspection control wiring line 55, and occurrence of undesired short-circuit or line breakage attributable to the discharge.

### EXAMPLE 2

### Conductive Layer-Inspection Control Wiring Line; Disposed in Different Layers

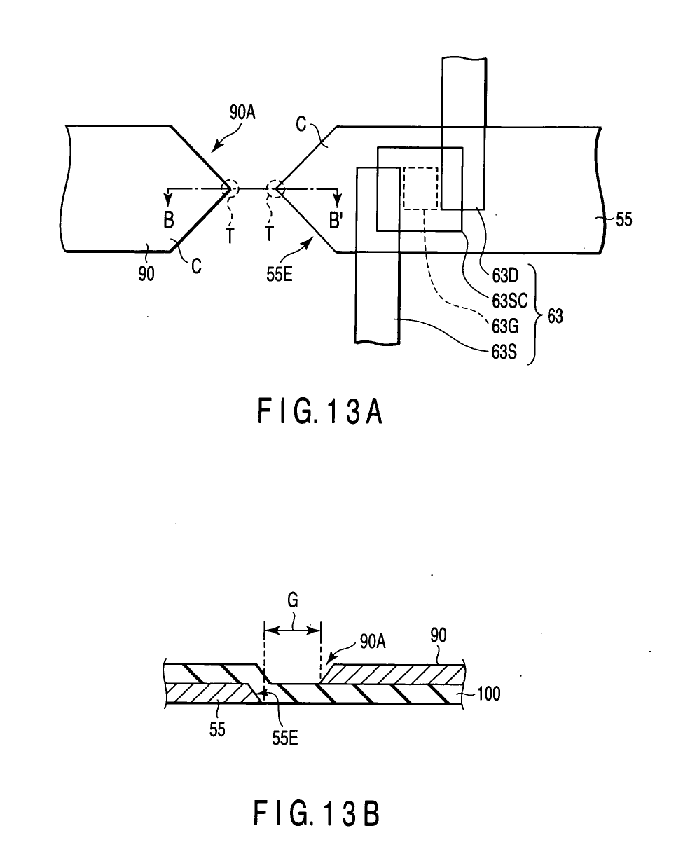

In Example 2, a constitution example will be described in which discharge in an end portion 55E of an inspection control wiring line 55 is induced. As shown in FIGS. 13A and 13B, a conductive layer 90 is disposed in a lower layer of an insulating layer 100. The inspection control wiring line 55 integral with a gate electrode 63G of a switch element 63 is disposed in an upper layer of the insulating layer 100. The end portion 55E facing the conductive layer 90 of the inspection control wiring line 55 has a salient portion C that protrudes toward the conductive layer 90. A discharge inducing portion 90A that faces the inspection control wiring line 55 of the conductive layer 90 has a salient portion C that protrudes toward the inspection control wiring line 55. That is, the end portion 55E of the inspection control wiring line 55 is disposed in a layer different from that of the conductive layer 90 in such a manner that a vertex T of the salient portion C faces the conductive layer 90 at a predetermined interval G in a plane of an array substrate 3.

According to such constitution, it is possible to relieve electric charges concentrated on the end portion 55E of the inspection control wiring line 55 by the discharge with the conductive layer 90. Consequently, it is possible to prevent in advance undesired discharge in the vicinity of the end portion of the inspection control wiring line 55, and occurrence of undesired short-circuit or line breakage attributable to the discharge.

### EXAMPLE 3

### Conductive Layer-Inspection Control Wiring Line; Disposed in Different Layers and Partially Superimposed

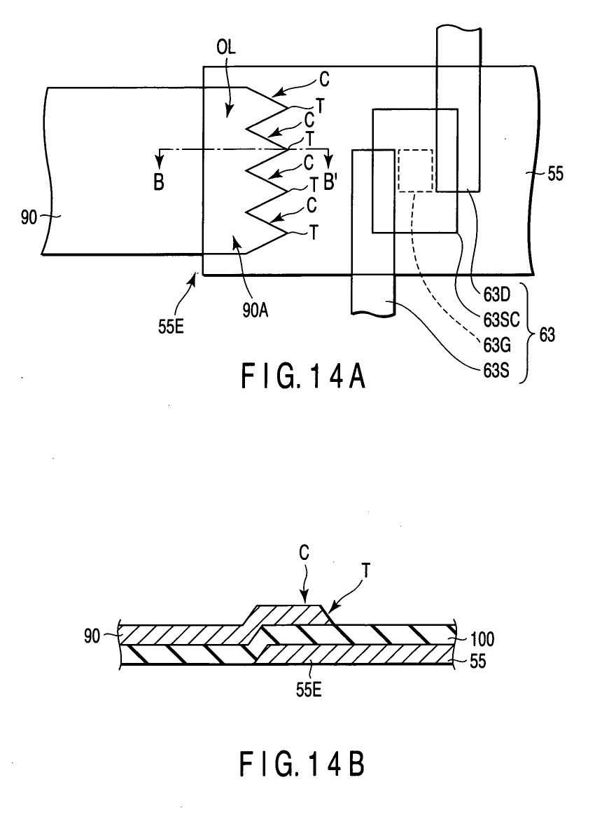

In Example 3, a constitution example will be described in which discharge in an end portion 55E of an inspection control wiring line 55 is induced. As shown in FIGS. 14A and 14B, a conductive layer 90 is disposed in an upper layer of an insulating layer 100. The inspection control wiring line 55 integral with a gate electrode 63G of a switch element 63 is disposed in a lower layer of the insulating layer 100. A portion of the inspection control wiring line 55 that faces the conductive layer 90, that is, the end portion 55E is formed to be broader than the conductive layer 90. The conductive layer 90 includes a discharge inducing portion 90A having a plurality of triangular salient portions C in the portion that faces the inspection control wiring line 55, and a part of the salient portion C including each vertex T overlaps with the end portion 55E of the inspection control wiring line 55. That is, the conductive layer 90 is disposed in a layer different from that of the inspection control wiring line 55, and is disposed in such a manner that at least a part of the conductive layer overlaps with the end portion 55E of the inspection control wiring line 55 via the insulating layer 100.

According to such constitution, it is possible to relieve electric charges concentrated on the end portion 55E of the inspection control wiring line 55 by the discharge with the conductive layer 90. Consequently, it is possible to prevent in advance undesired discharge in the vicinity of the end portion of the inspection control wiring line 55, and occurrence of undesired short-circuit or line breakage attributable to the discharge.

### EMBODIMENT 1

### Conductive Layer-Connection Pad or Connection Wiring Line

The above-described display device comprises a connection pad PD that enables connection to a driving IC chip 11 or a pad portion PP having a plurality of connection pads that enable connection to a flexible wiring board FPC.

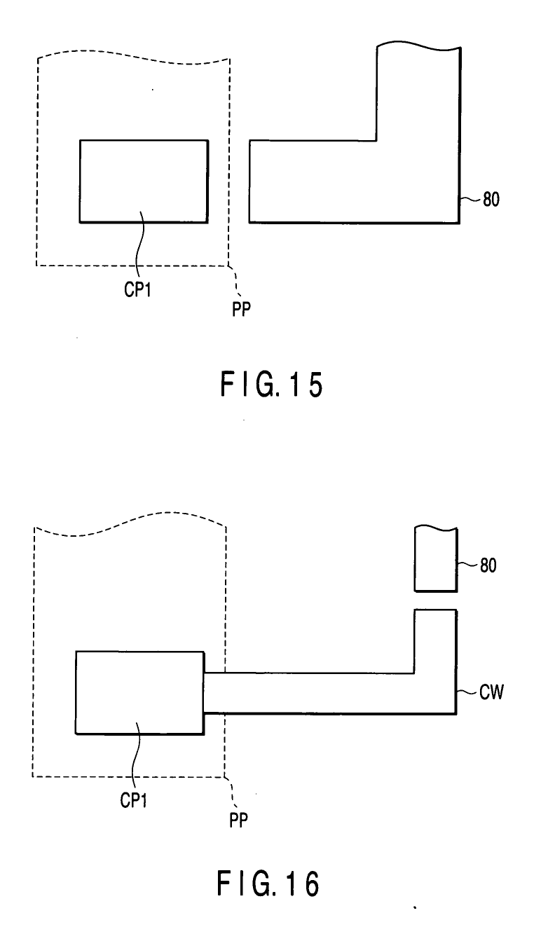

There will be described hereinafter a case where the above-described conductive layer 90 includes these connection pads or a connection wiring line connected to the connection pads. For example, as shown in FIG. 15, a connection pad CP1 included in the pad portion PP is disposed in such a manner as to face an inspection wiring line 80 at a predetermined interval. Alternatively, as shown in FIG. 16, a connection wiring line CW connected to the connection pad CP1 is disposed in such a manner as to face the inspection wiring line 80 at a predetermined interval.

The connection pad CP1 and the connection wiring line CW induce discharge of electric charges concentrated on the inspection wiring line 80. Even if the discharge occurs (or short-circuit or line breakage occurs as a result of the discharge), the conductive layer does not influence a completed liquid crystal display panel. That is, the connection pad CP1 and the connection wiring line CW constitute the conductive layer to which such a signal as to contribute to display in the liquid crystal display panel completed by connecting the flexible wiring board FPC to the pad portion PP is not input. That is, the connection pad CP1 and the connection wiring line CW constitute the conductive layer to which any signal is not input from a driving circuit of the flexible wiring board FPC after mounting the flexible wiring board FPC, the driving IC chip 11 and the like or to which such a signal as to fix switch elements 61, 62, and 63 disposed in an inspection section 40 in an off-state is input from the driving circuit of the flexible wiring board FPC.

When the conductive layer is utilized as the connection pad CP1 and the connection wiring line CW, a display quality level is not influenced in the completed liquid crystal display panel even if the layer short-circuits the inspection wiring line 80. If the discharge can be inhibited to such a small scale as to release electric charges from the inspection wiring line 80 without causing any short-circuit or line breakage, a conductive layer into which such a signal as to contribute to the display is input may be utilized as the connection pad CP1 and the connection wiring line CW.

Moreover, even in a case where the conductive layer 90 is the connection pad PD that enables the connection to the driving IC chip 11 and the connection wiring line connected to this connection pad PD, as shown in FIGS. 15 and 16, the connection pad PD or the connection wiring line may be disposed in such a manner as to face the inspection wiring line 80 at a predetermined interval. The connection pad PD and the connection wiring line may be a conductive layer into which such a signal as to contribute to the system is not input in the liquid crystal display panel completed by connecting the driving IC chip 11 to the connection pad PD.

A predetermined interval G between the connection pad CP1 or the connection wiring line CW and the inspection wiring line 80 is a distance in which the discharge can be induced, and is preferably as small as possible. However, when the connection pad or the connection wiring line and the inspection wiring line short-circuit (the interval is set to zero), a resistance becomes excessively small, and energy of electrostatic discharge damage cannot be consumed. Therefore, the interval is preferably such a distance that the connection pad or the connection wiring line and the inspection wiring line are brought into an electrically insulated state.

According to such constitution, it is possible to release the electric charges accumulated in the inspection wiring line 80 by means of the discharge with the connection pad CP1 or the connection wiring line CW. Consequently, it is possible to prevent in advance undesired discharge between the inspection wiring line 80 and another conductive layer adjacent to the inspection wiring line, and occurrence of undesired short-circuit or line breakage attributable to the discharge.

Therefore, in an inspection stage in which an inspection of a quality is performed in an effective display section 6 before mounting the flexible wiring board FPC or the driving IC chip 11, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 4

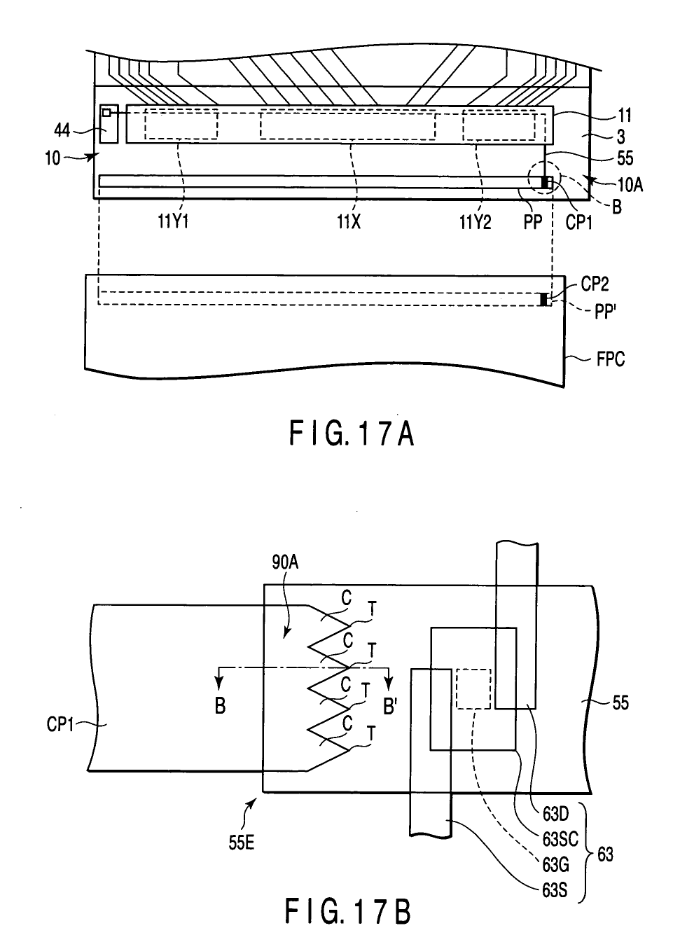

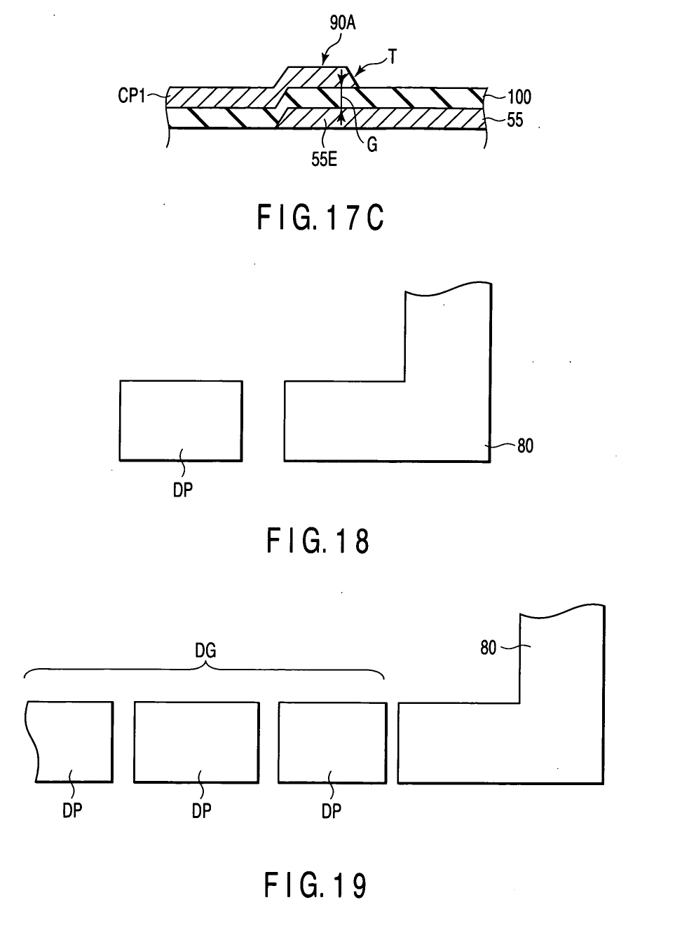

In Example 4, a constitution example will be described in which discharge in an end portion 55E of an inspection control wiring line 55 functioning as an inspection wiring line 80 is induced by a connection pad functioning as a conductive layer 90. As shown in FIG. 17A, an array substrate 3 is provided with a pad portion PP including a connection pad CP1 in an extension part 10A. The array substrate 3 is provided with the inspection control wiring line 55 integral with a gate electrode 63G of a switch element 63. On the other hand, a flexible wiring board FPC is provided with a wiring line portion PP′ including a connection pad CP2 connectable to the connection pad CP1 of the pad portion PP of the array substrate 3. When the pad portion PP of the array substrate 3 is electrically connected to the wiring line portion PP′ of the flexible wiring board FPC in such constitution, the connection pad CP1 is electrically connected to the connection pad CP2.

As shown in FIGS. 17B and 17C, the connection pad CP1 is disposed in an upper layer of an insulating layer 100. The inspection control wiring line 55 is disposed in a lower layer of the insulating layer 100. That is, the connection pad CP1 is disposed in a layer different from that of the inspection control wiring line 55. In addition, the pad is disposed in such a manner as to face the inspection control wiring line 55 at a predetermined interval G. Here, especially the connection pad CP1 is disposed in such a manner that at least a part (facing portion CA) overlaps with an end portion 55E of the inspection control wiring line 55 via the insulating layer 100.

A portion of the inspection control wiring line 55 that faces the connection pad CP1, that is, the end portion 55E is formed into a rectangular shape that is broader than that of the connection pad CP1. The connection pad CP1 is provided with a discharge inducing portion 90A including a plurality of triangular salient portions C in a portion facing the inspection control wiring line 55, and a part of each salient portion C including a vertex T overlaps with the end portion 55E of the inspection control wiring line 55. That is, the end portion 55E of the inspection control wiring line 55 is disposed to face the discharge inducing portion 90A of the connection pad CP1 at a predetermined interval G. In this case, the vertex T of each salient portion C included in the discharge inducing portion 90A faces the end portion 55E at the predetermined interval G substantially corresponding to a thickness of the insulating layer 100.

According to such constitution, electric charges concentrated on the end portion 55E of the inspection control wiring line 55 can be released by means of discharge with the connection pad CP1. In this case, since the vertexes T of the connection pad CP1 having such a shape that an electric field is easily concentrated is disposed to face the end portion 55E at the shortest distance, the discharge is easily induced in the vicinity of each vertex T. Consequently, it is possible to prevent in advance undesired discharge in the vicinity of the end portion of the inspection control wiring line 55, and occurrence of undesired short-circuit or line breakage attributable to the discharge.

### EMBODIMENT 2

### Conductive Layer-Dummy Pattern

The above-described display device is provided with a dummy pattern DP having an electrically floating state. Furthermore, the device includes a dummy group DG having a plurality of dummy patterns DP that are constituted of conductive members disposed in an island form and that are arranged at predetermined intervals in the electrically floating state. There will be described hereinafter a case where the above-described conductive layer 90 is the dummy pattern DP. For example, as shown in FIG. 18, the dummy pattern DP is disposed in such a manner as to face an inspection wiring line 80 at a predetermined interval. Alternatively, as shown in FIG. 19, at least one dummy pattern DP of the dummy group DG is disposed in such a manner as to face the inspection wiring line 80 at a predetermined interval.

These dummy patterns DP induce discharge of electric charges concentrated on the inspection wiring line 80. Even if the discharge occurs (or short-circuit or line breakage occurs as a result of the discharge), the conductive layer does not influence a completed liquid crystal display panel. That is, the dummy patterns DP constitute the conductive layer to which such a signal as to contribute to display in the liquid crystal display panel completed by connecting a flexible wiring board FPC, a driving IC chip 11 or the like is not input. That is, the dummy patterns DP constitute the conductive layer to which any signal is not input from a driving circuit of the flexible wiring board FPC, the driving IC chip 11 or the like after mounting the flexible wiring board, the driving IC chip and the like. When such conductive layer is utilized as the dummy pattern DP, a display quality level is not influenced in the completed liquid crystal display panel even if the layer short-circuits the inspection wiring line 80.

It is to be noted that the dummy patterns DP constituting the dummy group DG and the inspection wiring line 80 shown in FIG. 19 may be arranged in the same layer at predetermined intervals G as in a relation between the inspection wiring line 80 and a conductive layer 90 shown in FIGS. 6A and 6B. The dummy patterns DP and the inspection wiring line 80 may be disposed in different layers via an insulating layer 100 as in a relation between the inspection wiring line 80 and the conductive layer 90 shown in FIGS. 7A and 7B. Furthermore, the dummy patterns DP and the inspection wiring line 80 may be disposed in the different layers via the insulating layer 100 and disposed in such a manner that the inspection wiring line partially overlaps with the conductive layer as in a relation between the inspection wiring line 80 and the conductive layer 90 shown in FIGS. 8A and 8B.

Moreover, two adjacent dummy patterns DP constituting the dummy group DG shown in FIG. 19 may be arranged in the same layer at a predetermined interval G as in the relation between the inspection wiring line 80 and the conductive layer 90 shown in FIGS. 6A and 6B. The dummy patterns may be disposed in mutually different layers via the insulating layer 100 as in the relation between the inspection wiring line 80 and the conductive layer 90 shown in FIGS. 7A and 7B. Furthermore, the dummy patterns may be disposed in the mutually different layers via the insulating layer 100 and disposed in such a manner that the dummy patterns partially overlap with each other as in the relation between the inspection wiring line 80 and the conductive layer 90 shown in FIGS. 8A and 8B.

The predetermined interval G between the dummy pattern DP and the inspection wiring line 80, or the predetermined interval G between the dummy patterns DP constituting the dummy group DG is a distance in which the discharge can be induced, and is preferably as small as possible. However, when both of the dummy pattern and the inspection wiring line, or both of the dummy patterns short-circuit (the interval is set to zero), a resistance becomes excessively small, and energy of electrostatic discharge damage cannot be consumed. Therefore, the interval is preferably such a distance that both of the dummy pattern and the inspection wiring line, or both of the dummy patterns are brought into an electrically insulated state.

Moreover, in a case where the inspection wiring line 80 and the dummy pattern DP are formed at a close interval in the same layer, an exposure mask required for a patterning step needs to be prepared with a high precision, or the exposure mask needs to be positioned with the high precision in the patterning step. However, when the adjacent inspection wiring line 80 and dummy pattern DP, or two adjacent dummy patterns are formed in the different layers, it is not necessary to satisfy such requirement, and it is possible to reduce a manufacturing cost and enhance a manufacturing yield.

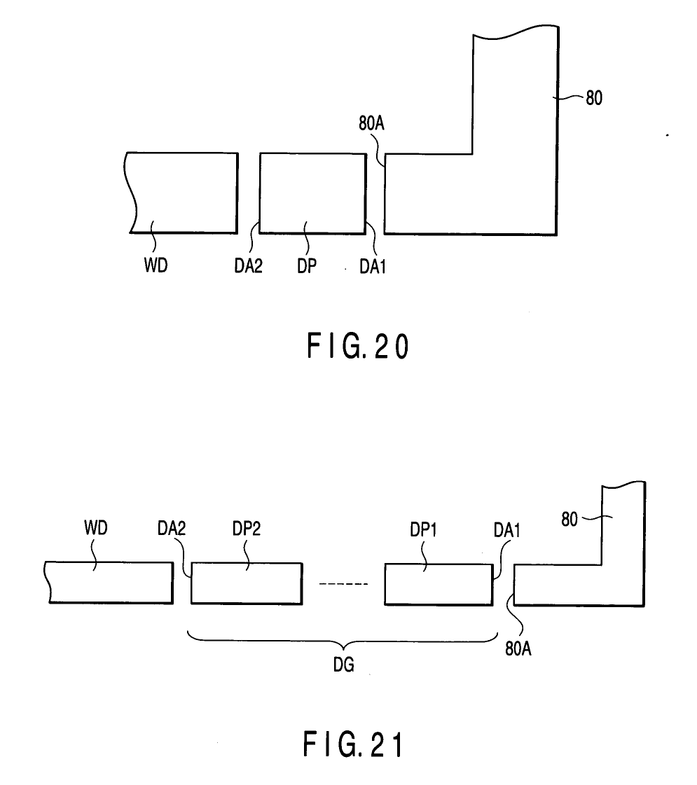

Moreover, as shown in FIG. 20, the dummy pattern DP may be disposed in such a manner that one end portion (i.e., the first facing portion) DA1 of the pattern faces the inspection wiring line 80 at a predetermined interval, and the other end portion (i.e., the second facing portion) DA2 faces a wiring line WD capable of supplying a predetermined signal (or the predetermined voltage) at a predetermined interval. In this case, the inspection wiring line 80, the dummy pattern DP, and the wiring line WD may be all disposed in the same layer as shown in FIGS. 6A and 6B, at least one of them may be disposed in a different layer via an insulating layer as shown in FIGS. 7A and 7B, and they may be disposed in such a manner that a part of at least one of them overlaps with the other component in the different layer via the insulating layer as shown in FIGS. 8A and 8B.

Furthermore, as shown in FIG. 21, the dummy group DG may include: a first dummy pattern DP1 whose one end portion DA1 is disposed in such a manner as to face the inspection wiring line 80 at a predetermined interval; and a second dummy pattern DP2 disposed in such a manner that one end portion DA2 faces the wiring line WD that is capable of supplying the predetermined signal (or the predetermined voltage) at a predetermined interval. In this case, the inspection wiring line 80, the dummy patterns DP constituting the dummy group DG, and the wiring line WD may be all disposed in the same layer as shown in FIGS. 6A and 6B, at least one of them may be disposed in the different layer via the insulating layer as shown in FIGS. 7A and 7B, and they may be disposed in such a manner that a part of at least one of them overlaps with the other component in the different layer via the insulating layer as shown in FIGS. 8A and 8B.

The wiring line WD shown in FIGS. 20 and 21 is a wiring line into which any signal is not input from driving circuits of a flexible wiring board FPC, a driving IC chip and the like after mounting the flexible wiring board, the driving IC chip and the like or into which such a signal as to fix switch elements 61, 62, and 63 disposed in an inspection section 40 in an off-state is input from these driving circuits. If the discharge can be inhibited to such a small scale as to release electric charges from the inspection wiring line 80 without causing any short-circuit or line breakage, the wiring line WD may be the wiring line into which such a signal as to contribute to the display is input.

According to such constitution, the electric charges accumulated in the inspection wiring line 80 can be released by means of the discharge with the dummy pattern DP. Consequently, it is possible to prevent in advance undesired discharge between the inspection wiring line 80 and another adjacent conductive layer, and occurrence of undesired short-circuit or line breakage attributable to the discharge.

Therefore, in an inspection stage in which an inspection of a quality is performed in an effective display section 6 before mounting the flexible wiring board FPC or the driving IC chip 11, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 5

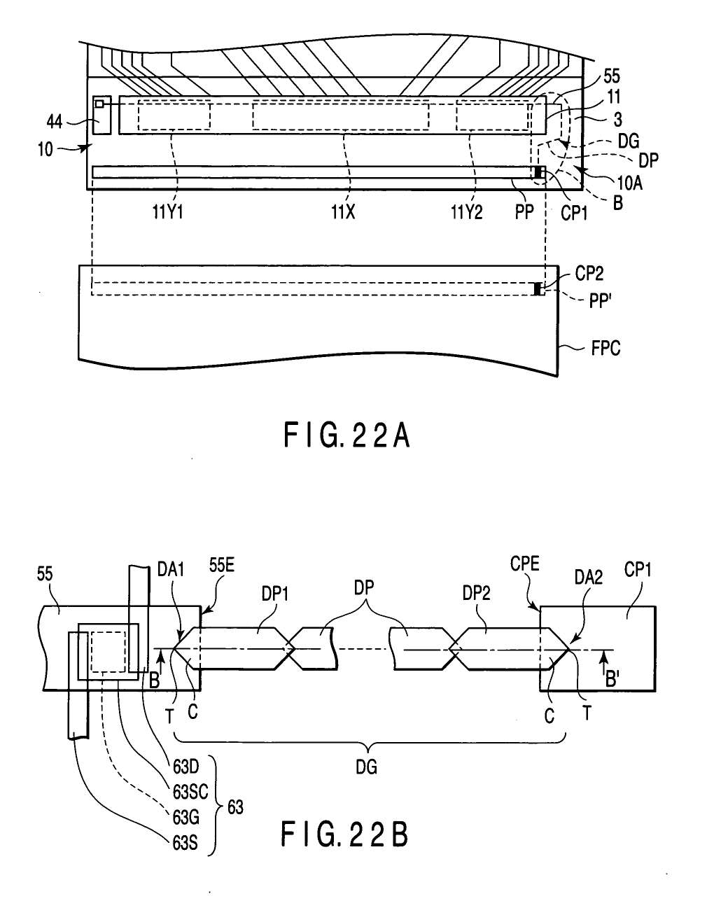

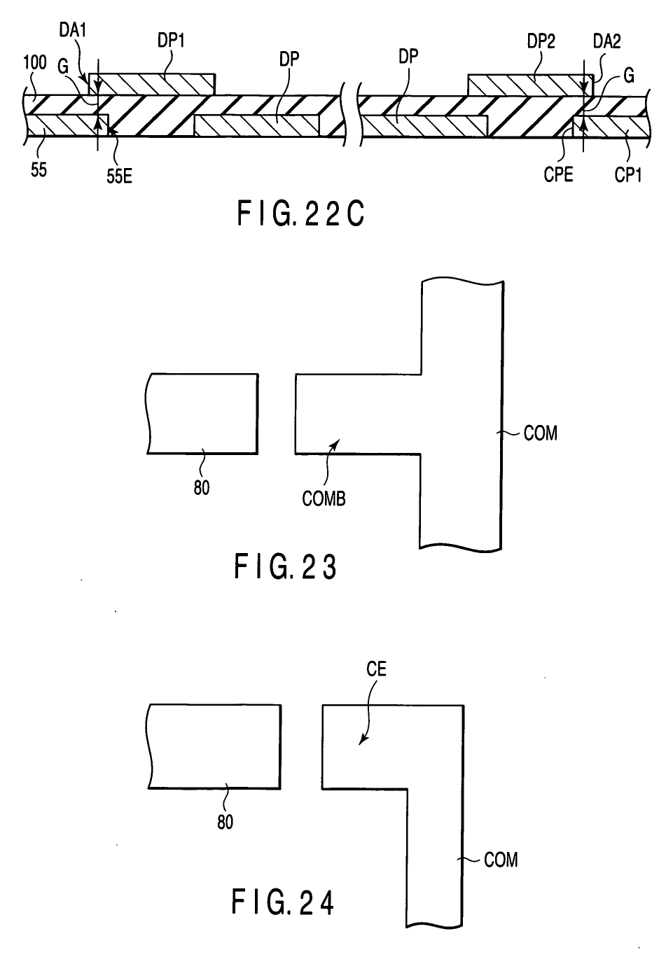

In Example 5, a constitution example will be described in which discharge in an end portion 55E of an inspection control wiring line 55 functioning as an inspection wiring line 80 is induced by a dummy pattern functioning as a conductive layer 90. As shown in FIG. 22A, an array substrate 3 is provided with a pad portion PP including a connection pad CP1 in an extension part 10A. The array substrate 3 is also provided with the inspection control wiring line 55 integral with a gate electrode 63G of a switch element 63. On the other hand, a flexible wiring board FPC is provided with a wiring line portion PP′ including a connection pad CP2 connectable to the connection pad CP1 of the pad portion PP of the array substrate 3. When the pad portion PP of the array substrate 3 is electrically connected to the wiring line portion PP′ of the flexible wiring board FPC in such constitution, the connection pad CP1 is electrically connected to the connection pad CP2.

Moreover, a dummy group DG constituted of a plurality of dummy patterns DP is disposed between the inspection control wiring line 55 and the connection pad CP1. That is, as shown in FIGS. 22B and 22C, the dummy group DG includes: a first dummy pattern DP1 disposed in such a manner as to face the inspection control wiring line 55 at a predetermined interval; and a second dummy pattern DP2 disposed in such a manner as to face the connection pad CP1 at a predetermined interval. The other dummy patterns DP constituting the dummy group DG are disposed in a layer different from that of the first and second dummy patterns DP1 and DP2 via an insulating layer 100.

The first dummy pattern DP1 is disposed in the layer different from that of the inspection control wiring line 55 via the insulating layer 100. Here, especially the first dummy pattern DP1 is disposed in such a manner that at least a part (facing portion DA1) of the pattern overlaps with an end portion 55E of the inspection control wiring line 55 via the insulating layer 100. The second dummy pattern DP2 is disposed in a layer different from that of the connection pad CP1 via the insulating layer 100. Here, especially the second dummy pattern DP2 is disposed in such a manner that at least a part (facing portion DA2) of the pattern overlaps with an end portion CPE of the connection pad CP1 via the insulating layer 100.

A portion of the inspection control wiring line 55 that faces the first dummy pattern DP1, that is, the end portion 55E is formed into a rectangular shape that is broader than that of the first dummy pattern DP1. A portion of the connection pad CP1 that faces the second dummy pattern DP2, that is, the end portion CPE is formed into a rectangular shape that is broader than that of the second dummy pattern DP2.

A portion DA1 of the first dummy pattern DP1 that faces the inspection control wiring line 55 functions as a discharge inducing portion. This facing portion DA1 has a triangular salient portion C, and a part of the salient portion C including a vertex T overlaps with the end portion 55E of the inspection control wiring line 55. That is, the end portion 55E of the inspection control wiring line 55 is disposed to face the facing portion DA1 of the first dummy pattern DP1 at a predetermined interval G. In this case, the vertex T of the salient portion C included in the facing portion DA1 faces the end portion 55E at the predetermined interval G substantially corresponding to a film thickness of the insulating layer 100.

A portion DA2 of the second dummy pattern DP2 that faces the connection pad CP1 has a triangular salient portion C, and a part of the salient portion C including a vertex T overlaps with the end portion CPE of the connection pad CP1. That is, the end portion CPE of the connection pad CP1 is disposed to face the facing portion DA2 of the second dummy pattern DP2 at a predetermined interval G. In this case, the vertex T of the salient portion C included in the facing portion DA2 faces the end portion CPE at the predetermined interval G substantially corresponding to the film thickness of the insulating layer 100.

According to such constitution, it is possible to release electric charges concentrated on the end portion 55E of the inspection control wiring line 55 by means of discharge with the first dummy pattern DP1, discharge with the other arranged dummy patterns, and discharge with the connection pad. CP1 disposed in the vicinity of the second dummy pattern DP2 of the dummy group DG. In this case, since the vertex T of the dummy pattern having such a shape that an electric field is easily concentrated is disposed to face the end portion 55E at the shortest distance, the discharge is easily induced in the vicinity of the vertex T. Consequently, it is possible to prevent in advance undesired discharge in the vicinity of the end portion of the inspection control wiring line 55, and occurrence of undesired short-circuit or line breakage attributable to the discharge.

### EMBODIMENT 3

### Conductive Layer-Common Wiring Line

The above-described display device is provided with a common wiring line COM that supplies a potential common to a plurality of display pixels PX in an effective display section 6. There will be described hereinafter a case where the above-described conductive layer 90 is the common wiring line COM. For example, as shown in FIGS. 23 and 24, the common wiring line COM is disposed in such a manner as to face an inspection wiring line 80 at a predetermined interval. In the example shown in FIG. 23, the common wiring line COM has a branched portion COMB, and this branched portion COMB faces the inspection wiring line 80 at the predetermined interval. In the example shown in FIG. 24, a terminal end portion CE of the common wiring line COM faces the inspection wiring line 80 at the predetermined interval.

The common wiring line COM induces discharge of electric charges concentrated on the inspection wiring line 80. The line is a conductive layer that does not influence a completed liquid crystal display panel even if the discharge occurs. That is, the common wiring line COM is a wiring line for supplying to a counter-electrode 9 a potential that is common to all display pixels PX. Although it is unfavorable to cause short-circuit or line breakage in the common wiring line COM as a result of the discharge, the common wiring line COM can be utilized in inducing the discharge, if the discharge can be inhibited to such a small scale as to release the electric charges from the inspection wiring line 80 without causing any short-circuit or line breakage.

A predetermined interval G between the common wiring line COM and the inspection wiring line 80 is a distance in which the discharge can be induced, and is preferably as small as possible. However, when both of the lines short-circuit (the interval is set to zero), a resistance becomes excessively small, and energy of electrostatic discharge damage cannot be consumed. Therefore, the interval is preferably such a distance that both of the lines are brought into an electrically insulated state.

According to such constitution, it is possible to release the electric charges concentrated on the inspection wiring line 80 by means of the discharge with the common wiring line COM. Consequently, it is possible to prevent in advance undesired discharge between the inspection wiring line 80 and another conductive layer adjacent to the line, and occurrence of undesired short-circuit or line breakage attributable to the discharge.

Therefore, in an inspection stage in which an inspection of a quality is performed in an effective display section 6 before mounting a flexible wiring board FPC or a driving IC chip 11, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 6

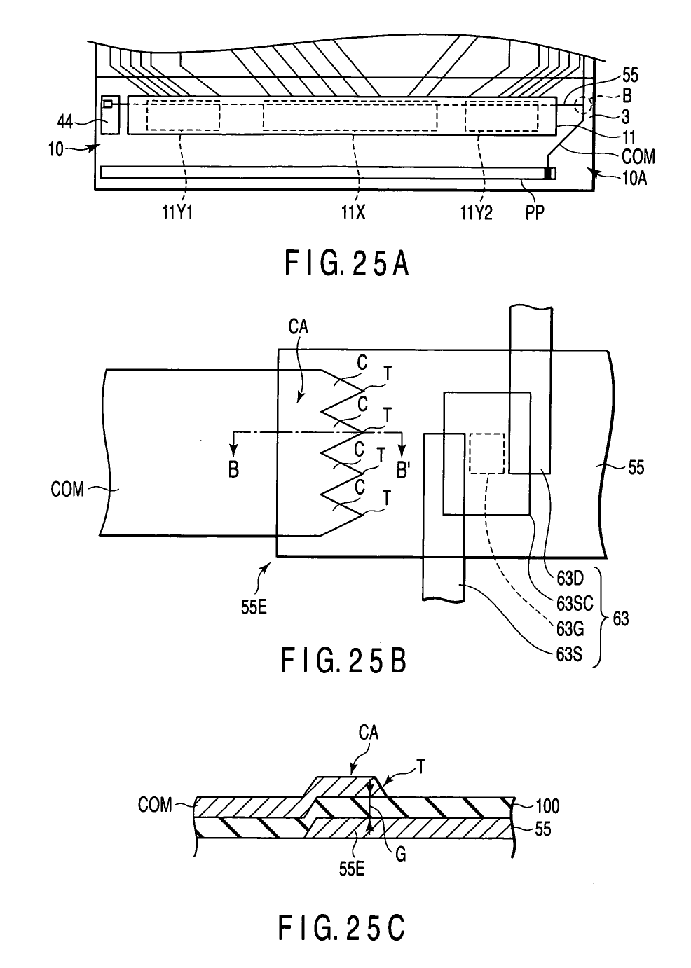

In Example 6, a constitution example will be described in which discharge in an end portion 55E of an inspection control wiring line 55 functioning as an inspection wiring line 80 is induced by a common wiring line COM functioning as a conductive layer 90. As shown in FIGS. 25A to 25C, an array substrate 3 is provided with the inspection control wiring line 55 integral with a gate electrode 63G of a switch element 63. The array substrate 3 is also provided with a common wiring line COM for supplying to a counter-substrate a potential that is common to all display pixels PX.

As shown in FIGS. 25B and 25C, the common wiring line COM is disposed in an upper layer of an insulating layer 100. The inspection control wiring line 55 is disposed in a lower layer of the insulating layer 100. That is, the common wiring line COM is disposed in a layer different from that of the inspection control wiring line 55, and the line is disposed in such a manner as to face the inspection control wiring line 55 at a predetermined interval G. Here, especially the common wiring line COM is disposed in such a manner that at least a part (facing portion CA) of the line overlaps with the end portion 55E of the inspection control wiring line 55 via the insulating layer 100.

A portion of the inspection control wiring line 55 that faces the common wiring line COM, that is, the end portion 55E is formed into a rectangular shape that is broader than that of the common wiring line COM. The portion CA of the common wiring line COM that faces the inspection control wiring line 55 functions as a discharge inducing portion. The facing portion CA has a plurality of triangular salient portions C, and a part of each salient portion C including a vertex T overlaps with the end portion 55E of the inspection control wiring line 55. That is, the end portion 55E of the inspection control wiring line 55 is disposed to face the facing portion CA of the common wiring line COM at the predetermined interval G. In this case, the vertex T of the salient portion C included in the facing portion CA faces the inspection control wiring line 55 at the predetermined interval G that substantially corresponds to a film thickness of the insulating layer 100.

According to such constitution, it is possible to release the electric charges concentrated on the end portion 55E of the inspection control wiring line 55 by means of discharge with the common wiring line COM. In this case, since the vertex T of the common wiring line COM having such a shape that an electric field is easily concentrated is disposed to face the end portion 55E at the shortest distance, the discharge is easily induced in the vicinity of the vertex T. Consequently, it is possible to prevent in advance undesired discharge in the vicinity of the end portion of the inspection control wiring line 55, and occurrence of undesired short-circuit or line breakage attributable to the discharge.

### EMBODIMENT 4

### Conductive Layer-Common Signal Line

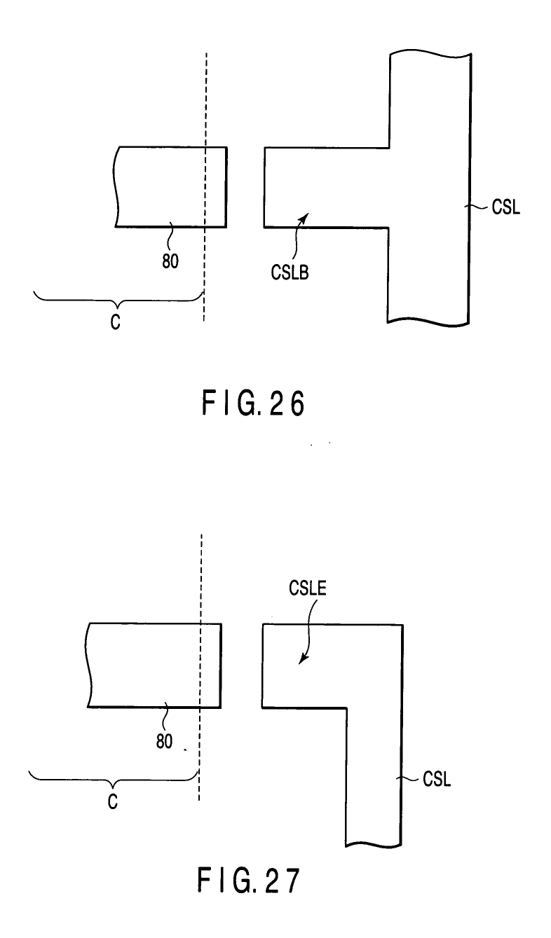

The above-described mother substrate for a display device is provided with a common signal line CSL for supplying a signal that is common to each cell region outside the cell region. There will be described hereinafter a case where the above-described conductive layer 90 is the common signal line CSL. In this case, an inspection wiring line 80 is drawn out of each cell region. For example, as shown in FIGS. 26 and 27, the common signal line CSL is disposed in such a manner as to face the inspection wiring line 80 drawn out of each cell region C at a predetermined interval outside the cell region. In the example shown in FIG. 26, the common signal line CSL has a branched portion CSLB, and this branched portion CSLB faces the inspection wiring line 80 at the predetermined interval. In the example shown in FIG. 27, a terminal end portion CSLE of the common signal line CSL faces the inspection wiring line 80 at the predetermined interval.

The common signal line CSL induces discharge of electric charges concentrated on the inspection wiring line 80. The line is a conductive layer that does not influence a completed liquid crystal display panel even if the discharge occurs (or short-circuit or line breakage occurs as a result of the discharge). That is, when the common signal line CSL is divided from the mother substrate into each cell region, the line does not remain in a liquid crystal display panel 1. When such conductive layer is utilized as the common signal line CSL, the layer does not influence a display quality level in the completed liquid crystal display panel even if the layer short-circuits the inspection wiring line 80.

A predetermined interval G between the common signal line CSL and the inspection wiring line 80 is a distance in which the discharge can be induced, and is preferably as small as possible. However, when both of the lines short-circuit (the interval is set to zero), a resistance becomes excessively small, and energy of electrostatic discharge damage cannot be consumed. Therefore, the interval is preferably such a distance that both of the lines are brought into an electrically insulated state.

According to such constitution, it is possible to release the electric charges accumulated in the inspection wiring line 80 by means of the discharge with the common signal line CSL. Consequently, it is possible to prevent in advance undesired discharge between the inspection wiring line 80 and another conductive layer adjacent to the line, and occurrence of undesired short-circuit or line breakage attributable to the discharge.

Therefore, in an inspection stage in which an inspection of a quality is performed in an effective display section 6 before mounting a flexible wiring board FPC or a driving IC chip 11, especially before dividing the mother substrate into individual liquid crystal display panels, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 7

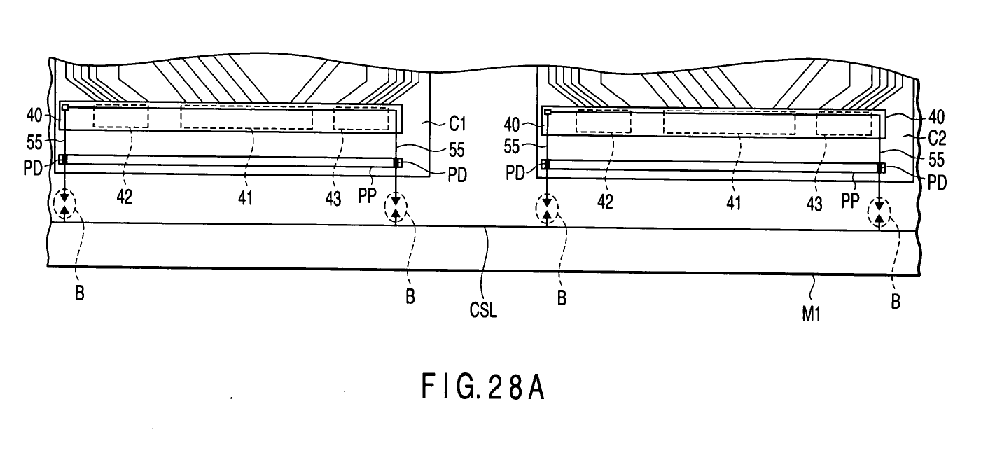

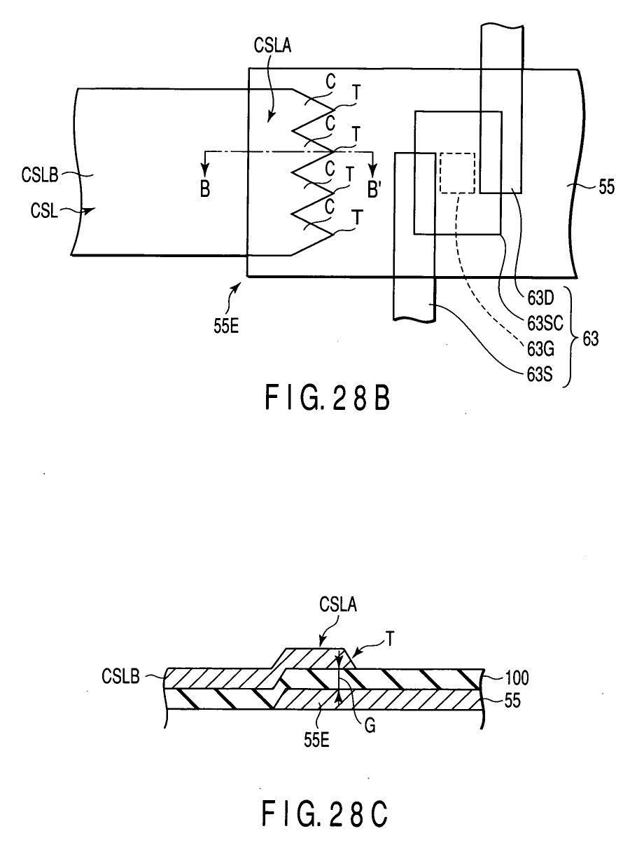

In Example 7, a constitution example will be described in which discharge in an end portion 55E of an inspection control wiring line 55 functioning as an inspection wiring line 80 is induced by a common signal line CSL functioning as a conductive layer 90. As shown in FIGS. 28A to 28C, a first mother substrate M1 for an array substrate is provided with inspection sections 40 in cell regions C1, C2 . . . . Each inspection section 40 is provided with the inspection control wiring line 55 integral with a gate electrode 63G of a switch element 63. This inspection control wiring line 55 is drawn out of the cell region C via a connection pad PD in a pad portion PP in the cell region C. On the other hand, the first mother substrate M1 is provided with a common signal line CSL for supplying a signal common to the respective cell regions C1, C2 . . . outside the cell region C.

In such constitution, the end portion 55E of the inspection control wiring line 55 disposed outside the cell region faces the common signal line CSL at a predetermined interval. In the example shown in FIGS. 28A to 28C, the end portion 55E faces a branched portion CSLB of the common signal line CSL. That is, as shown in FIGS. 28B and 28C, the branched portion CSLB is disposed in an upper layer of an insulating layer 100. The inspection control wiring line 55 is disposed in a lower layer of the insulating layer 100. That is, the branched portion CSLB is disposed in a layer different from that of the inspection control wiring line 55, and disposed in such a manner as to face the inspection control wiring line 55 at a predetermined interval G. Here, especially the branched portion CSLB is disposed in such a manner that at least a part (facing portion CSLA) of the portion overlaps with the end portion 55E of the inspection control wiring line 55 via the insulating layer 100.

A portion of the inspection control wiring line 55 that faces the branched portion CSLB, that is, the end portion 55E is formed into a rectangular shape that is broader than that of the branched portion CSLB. The portion CSLA of the branched portion CSLB that faces the inspection control wiring line 55 functions as a discharge inducing portion. This facing portion CSLA has a plurality of triangular salient portions C, and a part of each salient portion C including a vertex T overlaps with the end portion 55E of the inspection control wiring line 55. That is, the end portion 55E of the inspection control wiring line 55 is disposed to face the facing portion CSLA of the branched portion CSLB at the predetermined interval G. In this case, the vertex T of the salient portion C included in the facing portion CSLA faces the end portion 55E at the predetermined interval G that substantially corresponds to a film thickness of the insulating layer 100.

According to such constitution, it is possible to release the electric charges concentrated on the end portion 55E of the inspection control wiring line 55 by means of discharge with the branched portion CSLB. In this case, since the vertex T of the branched portion CSLB having such a shape that an electric field is easily concentrated is disposed to face the end portion 55E at the shortest distance, the discharge is easily induced in the vicinity of the vertex T. Consequently, it is possible to prevent in advance undesired discharge in the vicinity of the end portion of the inspection control wiring line 55, and occurrence of undesired short-circuit or line breakage attributable to the discharge.

In the above-described example, the constitution example has been described in which the end portion of the inspection control wiring line is disposed to face the common signal line to induce the discharge in the inspection control wiring line. The end portion disposed to face the common signal line may be any portion of the wiring line, such as the branched portion branched from an intermediate portion of the inspection wiring line.

### EMBODIMENT 5

### Conductive Layer-Connecting Portion

The above-described display device is provided with a connecting portion CN that connects a common wiring line COM to a counter-electrode 9. There will be described hereinafter a case where a conductive layer 90 is a connecting portion CN.

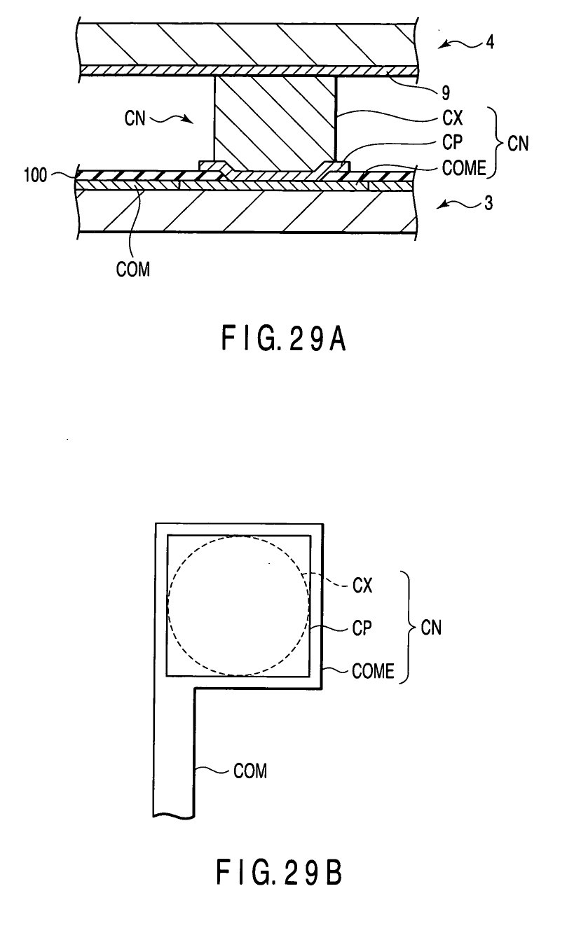

That is, as shown in FIGS. 29A and 29B, an array substrate 3 has the common wiring line COM for supplying a common potential in an outer peripheral part 10. A part of this common wiring line COM, such as an electrode portion COME formed in an end portion of the common wiring line COM, is exposed from an insulating layer 100. A power supply pad CP is connected to the exposed portion (e.g., the electrode portion COME) of the common wiring line COM. A connection member CX is a paste-like conductive member disposed on the power supply pad CP, and comes into contact with the counter-electrode 9 in a case where a counter-substrate 4 is laminated on the array substrate 3 to thereby connect the power supply pad CP to the counter-electrode 9.

That is, in the example shown in FIGS. 29A and 29B, the electrode portion COME, the power supply pad CP, and the connection member CX constitute the connecting portion CN. The connecting portion CN is disposed between the common wiring line COM and the counter-electrode 9, and the common potential is supplied from the common wiring line COM to the counter-electrode 9.

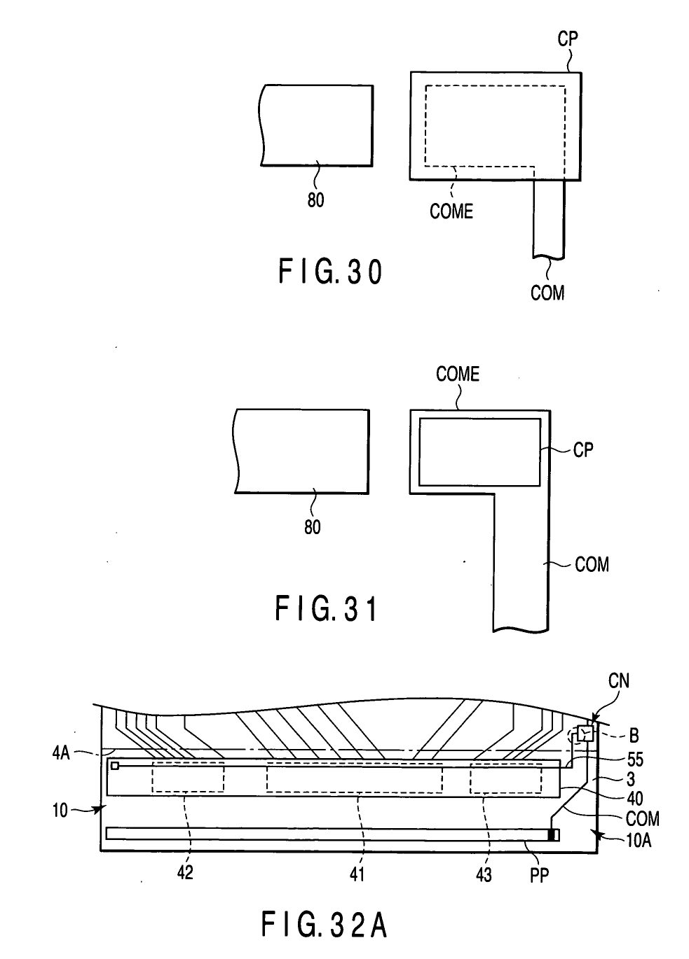

For example, as shown in FIGS. 30 and 31, the connecting portion CN is disposed in such a manner as to face the inspection wiring line 80 at a predetermined interval. In the example shown in FIG. 30, the power supply pad CP constituting the connecting portion CN has a size that is larger than that of the electrode portion COME of the common wiring line COM, and the power supply pad CP faces the inspection wiring line 80 at the predetermined interval. In the example shown in FIG. 31, the electrode portion COME of the common wiring line COM constituting the connecting portion CN has a size that is larger than that of the power supply pad CP, and the electrode portion COME faces the inspection wiring line 80 at the predetermined interval.

This connecting portion CN induces discharge of electric charges concentrated on the inspection wiring line 80. The portion is a conductive layer that does not influence a completed liquid crystal display panel even if the discharge occurs. That is, the connecting portion CN is a conductive member for supplying to the counter-electrode 9 a potential that is common to all display pixels PX in the liquid crystal display panel completed by connecting a flexible wiring board FPC, a driving IC chip and the like. Although it is unfavorable to cause short-circuit or line breakage in the connecting portion CN as a result of the discharge, the connecting portion CN can be utilized in inducing the discharge, if the discharge can be inhibited to such a small scale as to release the electric charges from the inspection wiring line 80 without causing any short-circuit or line breakage. In short, the connecting portion CN may be either the electrode portion COME or the power supply pad CP.

The predetermined interval G between the connecting portion CN and the inspection wiring line 80 is such a distance as to induce the discharge, and is preferably as small as possible. However, when both of the connecting portion and the inspection wiring line short-circuit (the interval is set to zero), a resistance becomes excessively small, and energy of electrostatic discharge damage cannot be consumed. Therefore, the interval is preferably set to such a distance that both of them are electrically insulated.

According to such constitution, it is possible to release the electric charges accumulated in the inspection wiring line 80 by means of discharge with the connecting portion CN. Consequently, it is possible to prevent in advance undesired discharge between the inspection wiring line 80 and another conductive layer adjacent to the line, and occurrence of undesired short-circuit or line breakage attributable to the discharge.

Therefore, in an inspection stage in which an inspection of a quality is performed in an effective display section 6 before mounting a flexible wiring board FPC or a driving IC chip 11, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 8

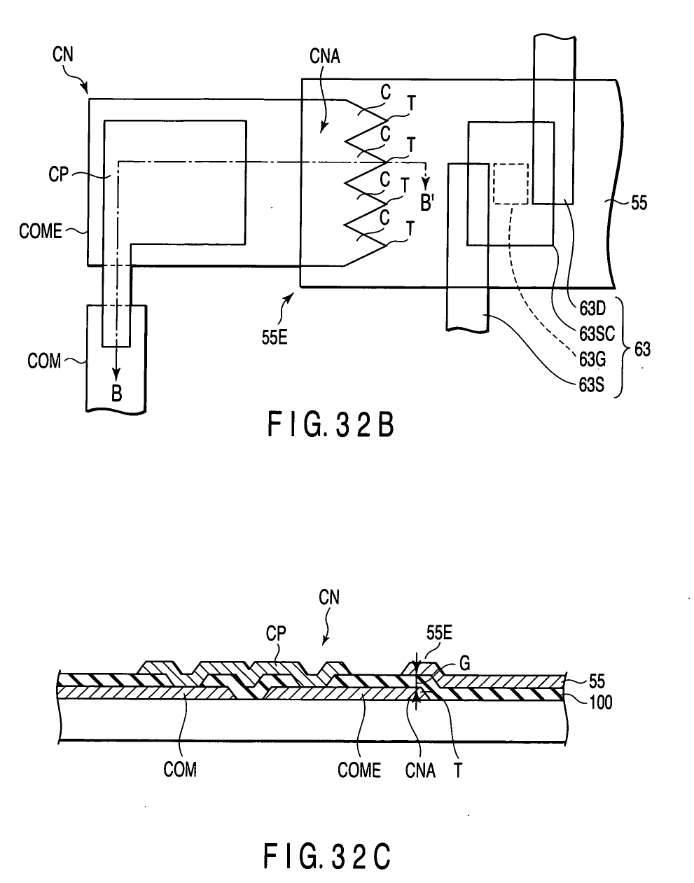

In this Example 8, a constitution example will be described in which discharge in an end portion 55E of an inspection control wiring line 55 functioning as an inspection wiring line 80 is induced by a connecting portion CN functioning as a conductive layer 90. As shown in FIGS. 32A to 32C, an array substrate 3 is provided with an inspection section 40 in an extension part 10A. The inspection section 40 has the inspection control wiring line 55 integral with a gate electrode 63G of a switch element 63. The array substrate 3 is also provided with a common wiring line COM for supplying to a counter-substrate a potential that is common to all display pixels PX. This common wiring line COM is connected to the connecting portion CN in a position that faces the counter-substrate.

In such constitution, the end portion 55E of the inspection control wiring line 55 faces the connecting portion CN at a predetermined interval.

That is, as shown in FIGS. 32B and 32C, the common wiring line COM is disposed in an outer peripheral part 10 of the array substrate 3. An electrode portion COME is formed into an independent island shape apart from the common wiring line COM. These common wiring line COM and electrode portion COME are disposed in a lower layer of an insulating layer 100, and a part of each of them is exposed from the insulating layer 100. A power supply pad CP is disposed in an upper layer of the insulating layer 100. This power supply pad CP electrically connects the common wiring line COM to the electrode portion COME via a contact hole extending through the insulating layer 100. The power supply pad CP is formed into a size that is substantially smaller than that of the electrode portion COME.

The inspection control wiring line 55 is disposed in the upper layer of the insulating layer 100. That is, the electrode portion COME is disposed in a layer different from that of the inspection control wiring line 55. In addition, the electrode portion is disposed in such a manner as to face the inspection control wiring line 55 at a predetermined interval G. Here, especially the electrode portion COME is disposed in such a manner that at least a part (facing portion CNA) of the portion overlaps with the end portion 55E of the inspection control wiring line 55 via the insulating layer 100.

The portion of the inspection control wiring line 55 that faces the electrode portion COME, that is, the end portion 55E is formed into a rectangular shape that is broader than that of the electrode portion COME. The facing portion CNA of the electrode portion COME facing the inspection control wiring line 55 functions as a discharge inducing portion. This facing portion CNA has a plurality of triangular salient portions C, and a part of each salient portion C including a vertex T overlaps with the end portion 55E of the inspection control wiring line 55. That is, the end portion 55E of the inspection control wiring line 55 is disposed in such a manner as to face the facing portion CNA of the electrode portion COME at the predetermined interval G. In this case, the vertex T of the salient portion C included in the facing portion CNA faces the end portion 55E at the predetermined interval G that substantially corresponds to the film thickness of the insulating layer 100.

According to such constitution, it is possible to release the electric charges concentrated on the end portion 55E of the inspection control wiring line 55 by means of the discharge with the electrode portion COME. In this case, since the vertex T of the electrode portion COME having such a shape that an electric field is easily concentrated is disposed to face the end portion 55E at the shortest distance, the discharge is easily induced in the vicinity of the vertex T. Consequently, it is possible to prevent in advance undesired discharge in the vicinity of the end portion of the inspection control wiring line 55, and occurrence of undesired short-circuit or line breakage attributable to the discharge.

### EMBODIMENT 6

### Conductive Layer-Alignment Mark

The above-described display device is provided with an alignment mark AMP required for positioning a display panel and components in mounting the components on the display panel constituted of an effective display section 6 and an inspection wiring line 80. A mother substrate for the above-described display device is provided with an alignment mark AMM disposed outside a cell region and required for positioning the mother substrate for the display device in a manufacturing process. There will be described hereinafter in a case where the above-described conductive layer 90 is the alignment mark AMP or AMM.

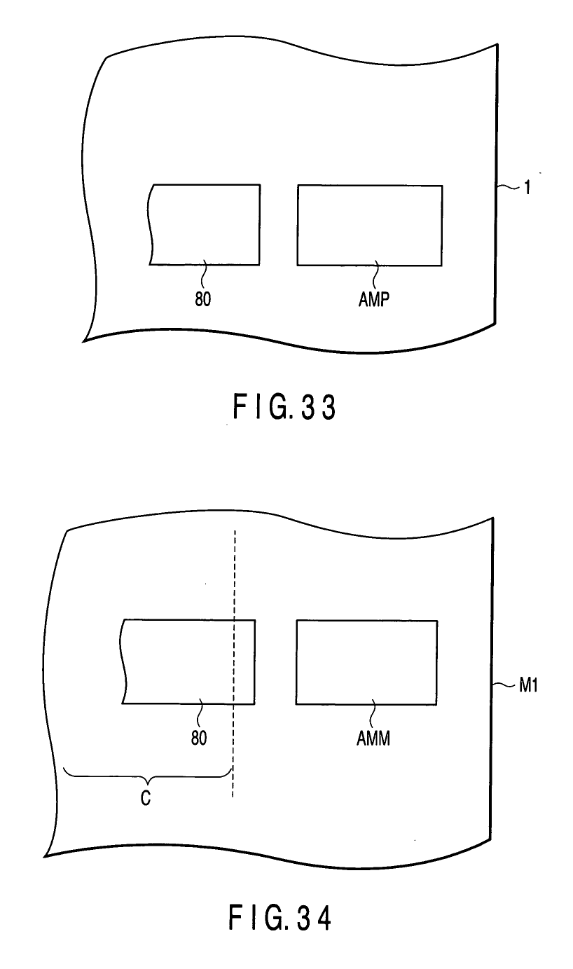

For example, as shown in FIG. 33, in a liquid crystal display panel 1, the alignment mark AMP is disposed in such a manner as to face the inspection wiring line 80 at a predetermined interval. As to the mother substrate for the display device, as shown in FIG. 34, the alignment mark AMM is disposed in such a manner as to face the inspection wiring line 80 drawn out of each cell region C at a predetermined interval outside the cell region C in a first mother substrate M1.

These alignment marks AMP and AMM induce discharge of electric charges concentrated on the inspection wiring line 80, and are conductive layers that do not influence the completed liquid crystal display panel even if the discharge occurs (or short-circuit or line breakage occurs as a result of the discharge). That is, the alignment mark AMP is a conductive layer into which such a signal as to contribute to display in the liquid crystal display panel completed by connecting a flexible wiring board FPC, a driving IC chip and the like is not input. The alignment mark AMM is a conductive layer that does not remain in the liquid crystal display panel 1 when the display device mother substrate is divided into the respective liquid crystal display panels 1.

In a case where such alignment marks AMP and AMM are utilized as the conductive layers for inducing the discharge, even if the marks short-circuit the inspection wiring line 80, a display quality level of the completed liquid crystal display panel is not influenced.

The predetermined interval G between the alignment mark AMP or AMM and the inspection wiring line 80 is a distance capable of inducing the discharge, and is preferably as small as possible. However, when both of the mark and the wiring line short-circuit (the interval is set to zero), a resistance becomes excessively small, and energy of electrostatic discharge damage cannot be consumed. Therefore, the interval G is preferably such a distance that both of them are electrically insulated.

According to such constitution, it is possible to release the electric charges accumulated in the inspection wiring line 80 by means of the discharge with the alignment mark AMP or AMM. Consequently, it is possible to prevent in advance undesired discharge between the inspection wiring line 80 and another conductive layer adjacent to the line, and occurrence of undesired short-circuit or line breakage attributable to the discharge.

Therefore, in an inspection stage in which an inspection of a quality is performed in an effective display section 6 before mounting a flexible wiring board FPC or a driving IC chip 11 or before dividing a mother substrate into individual liquid crystal display panels, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 9

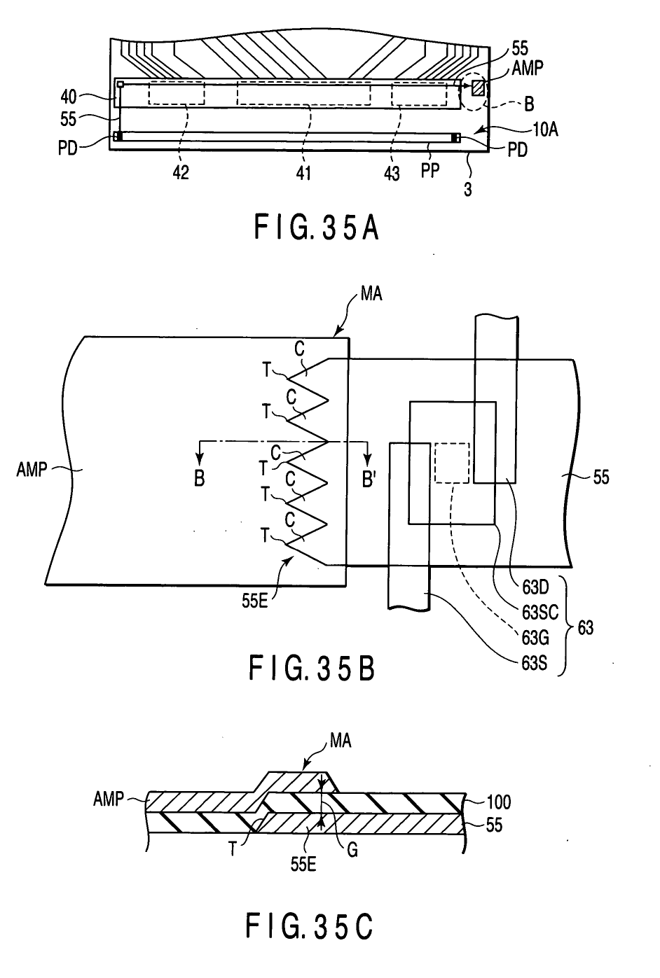

In Example 9, a constitution example will be described in which discharge in an end portion 55E of an inspection control wiring line 55 functioning as an inspection wiring line 80 is induced by an alignment mark AMP functioning as a conductive layer 90. As shown in FIGS. 35A to 35C, an array substrate 3 is provided with an inspection section 40 and the alignment mark AMP in an extension part 10A. The inspection section 40 is provided with the inspection control wiring line 55 integral with a gate electrode 63G of a switch element 63. In such constitution, the end portion 55E of the inspection control wiring line 55 faces the alignment mark AMP at a predetermined interval.

That is, as shown in FIGS. 35B and 35C, the alignment mark AMP is disposed in an upper layer of an insulating layer 100. The inspection control wiring line 55 is disposed in a lower layer of the insulating layer 100. That is, the alignment mark AMP is disposed in a layer that is different from that of the inspection control wiring line 55, and disposed in such a manner as to face the inspection control wiring line 55 at a predetermined interval G. Here, especially the alignment mark AMP is disposed in such a manner that at least a part (facing portion MA) of the mark overlaps with the end portion 55E of the inspection control wiring line 55 via the insulating layer 100.

The facing portion MA of the alignment mark AMP facing the inspection control wiring line 55 is formed into a rectangular shape that is broader than that of the inspection control wiring line 55. A portion of the inspection control wiring line 55 that faces the alignment mark AMP, that is, the end portion 55E functions as a discharge inducing portion. This end portion 55E has a plurality of triangular salient portions C, and a part of each salient portion C including a vertex T overlaps with the facing portion MA of the alignment mark AMP. That is, the end portion 55E of the inspection control wiring line 55 is disposed to face the facing portion MA of the alignment mark AMP at a predetermined interval G. In this case, the vertex T of the salient portion C included in the end portion 55E faces the facing portion MA at the predetermined interval G substantially corresponding to a film thickness of the insulating layer 100.

According to such constitution, it is possible to release the electric charges concentrated on the end portion 55E of the inspection control wiring line 55 by means of the discharge with the alignment mark AMP. In this case, the vertex T of the end portion 55E having such a shape that an electric field is easily concentrated is disposed to face the alignment mark AMP at the shortest distance, the discharge is easily induced in the vicinity of the vertex T. Consequently, it is possible to prevent in advance undesired discharge in the vicinity of the end portion of the inspection control wiring line 55, and occurrence of undesired short-circuit or line breakage attributable to the discharge.

In the above-described example, the constitution example has been described in which the end portion of the inspection control wiring line is disposed to face the alignment mark to induce the discharge in the inspection control wiring line, but the end portion disposed to face the alignment mark may be any portion of the wiring line, such as a branched portion branched from an intermediate portion of an inspection wiring line.

### EMBODIMENT 7

### Conductive Layer-Another Inspection Wiring Line

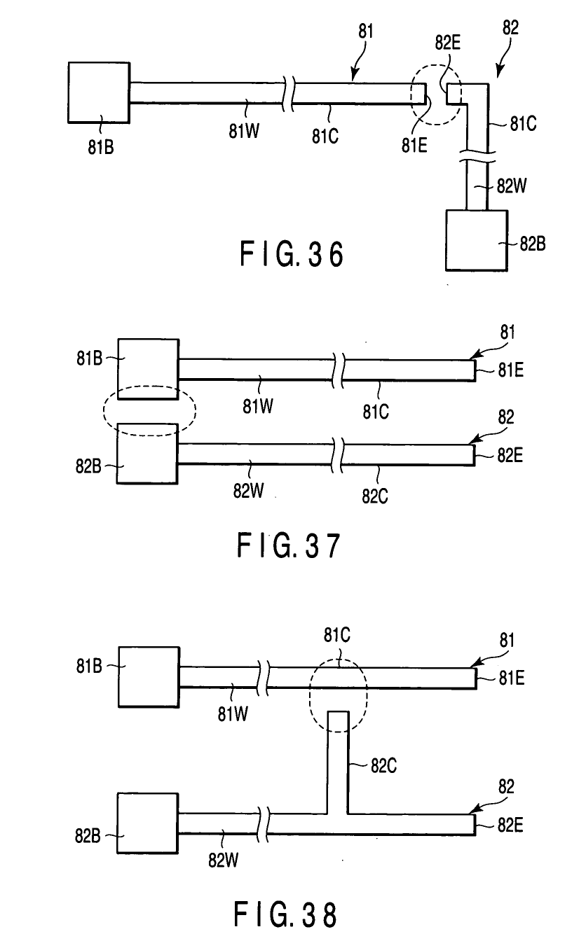

As shown in FIGS. 36 to 38, the above-described display device comprises a first inspection wiring line portion 81 having a first inspection wiring line 81W to which a first inspection signal is supplied in inspecting an effective display section 6 among a plurality of wiring lines for inspection; and a second inspection wiring line portion 82 including a second inspection wiring line 82W to which a second inspection signal different from the first inspection signal is supplied, and an input pad 82B for inputting the second inspection signal to the second inspection wiring line 82W. There will be described hereinafter a case where the above-described conductive layer 90 is the first inspection wiring line portion 81. That is, this second inspection wiring line portion 82 is disposed in such a manner that at least one of an end portion 82E of the second inspection wiring line 82W, the input pad 82B, and an intermediate portion 82C of the second inspection wiring line 82W faces the first inspection wiring line portion 81 at a predetermined interval at which the portion is closer to the first inspection wiring line portion 81 than the other portions of the second inspection wiring line portion 82 are.

In the example shown in FIG. 36, the second inspection wiring line portion 82 is disposed in such a manner that the end portion 82E of the second inspection wiring line 82W comes close to the first inspection wiring line portion 81. In the example shown in FIG. 37, the second inspection wiring line portion 82 is disposed in such a manner that the input pad 82B comes close to the first inspection wiring line portion 81. In the example shown in FIG. 38, the second inspection wiring line portion 82 is disposed in such a manner that the intermediate portion 82C (here, the branched portion branched from the second inspection wiring line 82W) of the second inspection wiring line 82W comes close to the first inspection wiring line portion 81. It is to be noted that the second inspection wiring line portion 82 is disposed to closely face the first inspection wiring line portion 81. This corresponds to a state in which a part of the second inspection wiring line portion 82 is close to a part of the first inspection wiring line portion 81, that is, any one of an end portion 81E of the first inspection wiring line 81W of the first inspection wiring line portion 81, an intermediate portion 81C of the first inspection wiring line, and an input pad 81B for inputting an inspection signal into the first inspection wiring line 81W.

That is, a portion surrounded with a dotted line in FIG. 36 shows a state in which the end portion 82E of the second inspection wiring line 82W is close to the end portion 81E of the first inspection wiring line portion 81, but the second inspection wiring line portion 82 may be disposed in such a manner that the end portion 82E of the second inspection wiring line 82W is close to the input pad 81B or the intermediate portion 81C of the first inspection wiring line 81W.

Similarly, a portion surrounded with a dotted line in FIG. 37 shows a state in which the input pad 82B of the second inspection wiring line 82W is close to the input pad 81B of the first inspection wiring line portion 81, but the second inspection wiring line portion 82 may be disposed in such a manner that the input pad 82B is close to the end portion 81E or the intermediate portion 81C of the first inspection wiring line 81W.

Similarly, a portion surrounded with a dotted line in FIG. 38 shows a state in which the intermediate portion 82C of the second inspection wiring line 82W is close to the intermediate portion 81C of the first inspection wiring line 81W, but the second inspection wiring line portion 82 may be disposed in such a manner that the intermediate portion 82C is close to the end portion 81E of the first inspection wiring line 81W or the input pad 81B.

These structures of the inspection wiring lines induce discharge of electric charges concentrated on the inspection wiring lines, and there is selected a wiring line for inspection that does not influence a completed liquid crystal display panel even if the discharge occurs between the inspection wiring lines. That is, the inspection wiring line is a conductive member for supplying mutually different signals in an inspection stage or in the liquid crystal display panel completed by connecting a flexible wiring board FPC, a driving IC chip and the like. Although it is unfavorable to cause short-circuit between the inspection wiring lines or line breakage of the inspection wiring line as a result of the discharge, the inspection wiring line can be utilized in inducing the discharge, if the discharge can be inhibited to such a small scale as to release the electric charges from the other inspection wiring line without causing any short-circuit or line breakage.

One example corresponds to a case where it is assumed that the second inspection wiring line portion 82 has inspection wiring lines such as an inspection control wiring line 55 on which electric charges are easily accumulated and a common wiring line COM, and the first inspection wiring line portion 81 has inspection wiring lines such as a signal line inspection driving wiring line 51 for inducing the discharge, a first inspection driving wiring line 52, and a second inspection driving wiring line 53. It is to be noted that when the second inspection wiring line portion 82 has the inspection control wiring line 55, the first inspection wiring line portion 81 may have the common wiring line COM.

A predetermined interval G between the first inspection wiring line portion 81 and the second inspection wiring line portion 82 is a distance capable of inducing the discharge, and is as small as possible. However, if both of the inspection wiring lines short-circuit (the interval is set to zero), a resistance becomes excessively small, and energy of electrostatic discharge damage cannot be consumed. Therefore, the interval is preferably such a distance that both of them are electrically insulated.

According to such constitution, it is possible to release the electric charges accumulated in the second inspection wiring line portion 82 by means of the discharge with the first inspection wiring line portion 81. Consequently, it is possible to prevent in advance undesired discharge between the second inspection wiring line portion 82 and another conductive layer adjacent to the portion, and occurrence of undesired short-circuit or line breakage attributable to the discharge.

Therefore, in an inspection stage in which an inspection of a quality is performed in an effective display section 6 before mounting a flexible wiring board FPC or a driving IC chip 11, it is possible to stably inspect wiring defects of various types of wiring lines by use of an inspection section 40, and defects can be prevented from being generated in the completed liquid crystal display panel. It is also possible to inhibit a drop of a manufacturing yield.

### EXAMPLE 10

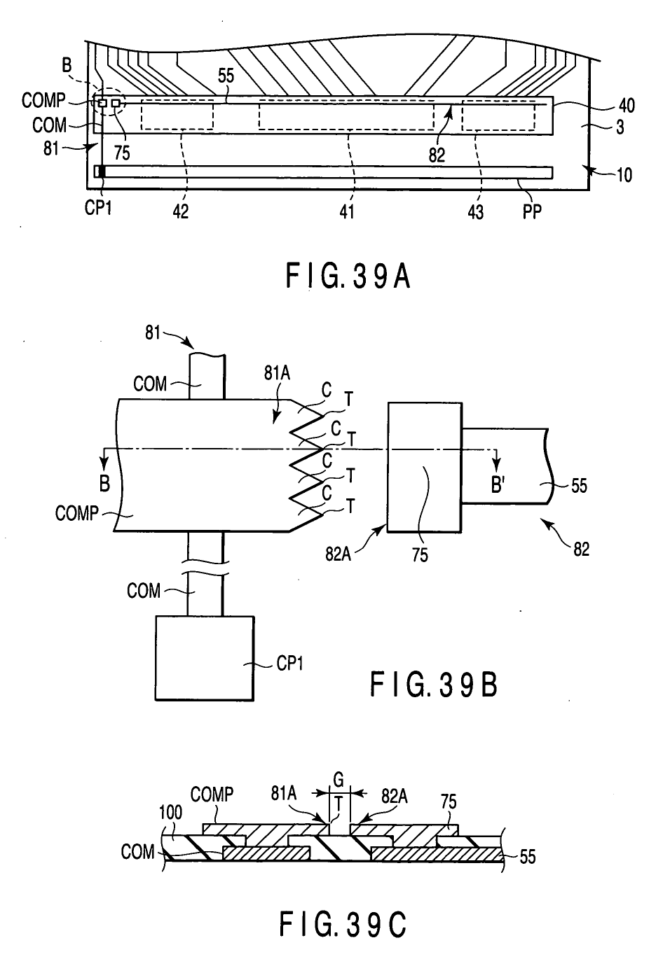

In Example 10, a constitution example will be described in which discharge in an inspection control wiring line 55 functioning as a second inspection wiring line 82W is induced by a first inspection wiring line portion 81 functioning as a conductive layer 90. As shown in FIGS. 39A to 39C, an array substrate 3 includes the first inspection wiring line portion 81 and a second inspection wiring line portion 82 in an outer peripheral part 10. The first inspection wiring line portion 81 is provided with a common wiring line (first inspection wiring line) COM and an input pad COMP for inputting a first inspection signal (signal of a common potential) into the common wiring line COM. The second inspection wiring line portion 82 is provided with: the inspection control wiring line (second inspection wiring line) 55 integral with a gate electrode 63G of a switch element 63 in an inspection section 40, and an input pad 75 for inputting a second inspection signal into the inspection control wiring line 55. The common wiring line COM is connected to a connection pad CP1 of a pad portion PP.

In such constitution, the second inspection wiring line portion 82 is disposed in such a manner that the input pad 75 faces the first inspection wiring line portion 81 at a predetermined interval at which the pad is closer to the first inspection wiring line portion than the other portions of the second inspection wiring line portion 82 are.

That is, as shown in FIGS. 39B and 39C, the inspection control wiring line 55 is disposed in a lower layer of an insulating layer 100. The input pad 75 is disposed in an upper layer of the insulating layer 100, and electrically connected to the inspection control wiring line 55 via a contact hole that extends through the insulating layer 100. The common wiring line COM is disposed in the lower layer of the insulating layer 100. An input pad COMP is disposed in the upper layer of the insulating layer 100, and electrically connected to the common wiring line COM via a contact hole that extends through the insulating layer 100.

A portion of the input pad 75 of the second inspection wiring line portion 82 facing the first inspection wiring line portion 81, that is, a portion 82A that faces the input pad COMP has a rectangular shape. A portion of the input pad COMP of the first inspection wiring line portion 81 facing the second inspection wiring line portion 82, that is, a portion 81A that faces the input pad 74 functions as a discharge inducing portion. This facing portion 81A has a plurality of triangular salient portions C, and a vertex T of each salient portion C is disposed close to the input pad 75.

That is, in Example 10, the input pad 75 of the second inspection wiring line portion 82 is disposed in the same layer as that of the input pad COMP of the first inspection wiring line portion 81, and disposed in such a manner as to face the input pad COMP at a predetermined interval G.

According to such constitution, it is possible to release the electric charges concentrated on the second inspection wiring line portion 82 by means of the discharge with the first inspection wiring line portion 81. In this case, each vertex T of the first inspection wiring line portion 81 (here the input pad COMP) having such a shape that an electric field is easily concentrated is disposed to face the first inspection wiring line portion 81 (here, the input pad 75) at the shortest distance, the discharge is easily induced in the vicinity of the vertex T. Consequently, it is possible to prevent in advance undesired discharge in the inspection control wiring line 55, and occurrence of undesired short-circuit or line breakage attributable to the discharge.

As described above, according to a display device of the present embodiments, when a conductive layer is disposed in an inspection wiring line in such a manner as to face a portion on which electric charges are easily concentrated in an array substrate having an inspection section, discharge can be induced. Consequently, it is possible to prevent such concentration of the electric charges as to enlarge a discharge scale in the inspection wiring line. Therefore, it is possible to inhibit undesired discharge between a conductive layer and another conductive layer close to the inspection wiring line, and occurrence of wiring defects attributable to this discharge.

Moreover, according to a mother substrate for the display device of the present embodiment, the inspection wiring line disposed in the inspection section in each cell region is drawn out of the cell region, and a conductive layer of this inspection wiring line, such as a common signal line or an alignment mark, is disposed in such a manner as to face the portion on which the electric charges are easily concentrated. It is accordingly possible to induce the discharge. Consequently, it is possible to prevent such concentration of the electric charges as to enlarge the discharge scale in the inspection wiring line. Therefore, it is possible to inhibit the undesired discharge between the conductive layer and the other conductive layer close to the inspection wiring line, and the occurrence of the wiring defects attributable to this discharge.

Therefore, in an inspection stage before mounting a driving IC chip, a flexible wiring line substrate and the like or before dividing a mother substrate into a plurality of liquid crystal display panels, it is possible to stably perform an inspection of a quality of an effective display section by use of the inspection section. Therefore, it is possible to prevent in advance outflow of the wiring defects into subsequent steps of the liquid crystal display panel. It is also possible to prevent defects from being generated in the completed liquid crystal display panel. Consequently, it is possible to inhibit a drop of a manufacturing yield.

It is to be noted that the present invention is not limited to the above-described embodiments as such, and constituting elements can be modified and embodied in a stage for carrying out the present invention without departing from the scope. Various inventions can be formed by an appropriate combination of a plurality of constituting elements disclosed in the above-described embodiments. For example, several constituting elements may be omitted from all the constituting elements described in the embodiment. Furthermore, the constituting elements of the different embodiments may be appropriately combined.

For example, in the above-described embodiments, the liquid crystal display panel has been described in which a scanning signal is supplied from opposite sides of the liquid crystal display panel, but the number of power supply wiring lines for the scanning signal in a first driving section may be different from that in a second driving section. The panel may have a layout in which the first or second driving section is not disposed, and the scanning signal is supplied to each scanning line from one side only by means of a single scanning line driving portion. Conversely, the scanning line driving section may further have third and fourth driving sections.

Moreover, the display device of the present invention is not limited to the above-described liquid crystal display, and may be another display device such as an organic electroluminescence display device including a display panel in which a self light emitting element is a display element.

What is claimed is:

1. A display device comprising:
an effective display section constituted of a plurality of display pixels;
a wiring line for inspection to which a signal for inspection is supplied in inspecting the effective display section; and
a conductive layer having a discharge inducing section which is disposed in such a manner as to face the wiring line for inspection at a predetermined interval and which induces discharge of electric charges accumulated in the wiring line for inspection.

2. The display device according to claim 1, wherein the conductive layer is disposed in the same layer as that of the inspection wiring line.

3. The display device according to claim 1, wherein the conductive layer is disposed in a layer which is different from that of the inspection wiring line via an insulating layer.

4. The display device according to claim 3, wherein the conductive layer is disposed in such a manner that at least a part of the conductive layer overlaps with the inspection wiring line via the insulating layer.

5. The display device according to claim 1, wherein the discharge inducing section has a salient portion which protrudes toward the inspection wiring line.

6. The display device according to claim 1, wherein a portion of the inspection wiring line which faces the discharge inducing section has a salient portion which protrudes toward the discharge inducing section.

7. The display device according to claim 1, wherein the inspection wiring line is a wiring line which supplies a potential common to a plurality of display pixels in the effective display section.

8. The display device according to claim 1, wherein the discharge inducing section is disposed in such a manner as to face an end portion of the inspection wiring line at a predetermined interval.

9. The display device according to claim 1, further comprising:
a wiring line connected to the effective display section and drawn out of the effective display section,
wherein the inspection wiring line includes an inspection driving wiring line which is connected to the wiring line via a switch element and to which an inspection driving signal is supplied in inspecting the effective display section; and an inspection control wiring line to which an inspection control signal to on/off-control the switch element is supplied in inspecting the effective display section, and
the conductive layer is disposed in such a manner as to face the inspection control wiring line at a predetermined interval.

10. The display device according to claim 9, wherein the wiring line is at least one of a scanning line and a signal line.

11. The display device according to claim 9, wherein the switch element is a thin-film transistor, and a gate electrode of the switch element is connected to the inspection control wiring line.

12. The display device according to claim 1, wherein the conductive layer is a conductive member disposed in an island form.

13. The display device according to claim 1, wherein the conductive layer is a wiring line which supplies a signal.

14. The display device according to claim 1, wherein the effective display section is disposed in a liquid crystal display panel constituted by holding a liquid crystal layer between an array substrate and a counter-substrate.

15. The display device according to claim 14, wherein the inspection wiring line is disposed on an extension part of the array substrate which extends outward from an end portion of the counter-substrate.

16. The display device according to claim 4, wherein the inspection wiring line is disposed in a region in which a driving IC chip is to be disposed.

17. The display device according to claim 1, further comprising:
a pad portion including a connection pad to be connected to a flexible wiring line substrate or to a driving IC chip having a driving circuit which supplies a driving signal to the effective display section;
wherein the conductive layer is the connection pad or a connection wiring line connected to the connection pad.

18. The display device according to claim 1, further comprising:
a dummy pattern having an electrically floating state,
wherein the conductive layer is the dummy pattern.

19. The display device according to claim 1, further comprising:
a common wiring line which supplies a potential common to a plurality of display pixels in the effective display section,
wherein the conductive layer is the common wiring line.

20. The display device according to claim 19, wherein the effective display section is disposed in a liquid crystal display panel constituted by holding a liquid crystal layer between an array substrate having a pixel electrode for each display pixel, and a counter-substrate having a counter-electrode facing a plurality of pixel electrodes,
the display device further comprising: a connecting portion which connects the common wiring line to the counter-electrode,
the conductive layer being the connecting portion.

21. The display device according to claim 1, further comprising:
an alignment mark required in positioning a display panel and components in a case where the components are mounted on the display panel having the effective display section and the inspection wiring line,
wherein the conductive layer is the alignment mark.

22. The display device according to claim 1, wherein the inspection wiring line includes a first inspection wiring line to which a first inspection signal is supplied and a second inspection wiring line to which a second inspection signal different from the first inspection signal is supplied in a case where the effective display section is inspected,
further comprising:
a first inspection wiring line portion having the first inspection wiring line, and a second inspection wiring line portion having the second inspection wiring line and an input pad which inputs the second inspection signal to the second inspection wiring line, and
wherein the second inspection wiring line portion is disposed in such a manner that at least one of an end portion of the second inspection wiring line, the input pad, and an intermediate portion of the second inspection wiring line faces the first inspection wiring line portion at a predetermined interval which is closer than that between another portion of the second inspection wiring line portion and the first inspection wiring line portion.

23. The display device according to claim 4, wherein at least one of a portion of the inspection wiring line which faces the discharge inducing section and the discharge inducing section has a plurality of salient portions having different lengths.

24. The display device according to claim 1, wherein the inspection wiring line is disposed in an outer peripheral portion positioned outside the effective display section.
